(19) United States
(12) Patent Application Publication
(10) Pub. No.: US 2011/0102002 A1
(43) Pub. Date: May 5, 2011

(54) ELECTRODE AND SENSOR HAVING CARBON NANOSTRUCTURES

(76) Inventors: Bill L. Riehl, Beavercreek, OH (US); Bonnie D. Riehl, Beavercreek, OH (US); Edward E. King, Dayton, OH (US); Jay M. Johnson, Dayton, OH (US); Kevin T. Schlueter, New Carlisle, OH (US)

(21) Appl. No.: 12/889,019

(22) Filed: Sep. 23, 2010

Related U.S. Application Data
(63) Continuation-in-part of application No. 12/763,799, filed on Apr. 20, 2010.
Application No. 12/763,799 is a continuation-in-part of application No. PCT/US2009/039737, filed on Apr. 7, 2009.
(60) Provisional application No. 61/043,514, filed on Apr. 9, 2008.

(51) Int. Cl. G01R 27/08; H01B 5/00; C40B 60/12; B82Y 30/00

(52) U.S. Cl. 324/693; 174/126.2; 506/39; 977/734; 977/742; 977/932

(57) ABSTRACT

An active electrode structure is disclosed that includes fullerenes produced by a carbo-thermal carbide conversion of a conductive carbide without a metal catalyst. Also disclosed is an electrode that includes a fullerene covalently bonded to a conductive carbide, the fullerene being an aligned or non-aligned array. The carbide substrate having a surface coating of covalently bonded fullerenes is characterized in that the peak separation of a cyclic voltammogram for the conductive carbide having a surface layer of the fullerene is less than about 150 mV at a scan rate of 5 mV/s in a 4 mM ferricyanide, 1M KCl solution. The fullerene may include about 50% or less non-crystalline carbon and about 5% or less of a transition metal that interferes with the ability of the active electrode structure to transfer electrons or detect an analyte.

### CROSS-REFERENCE TO RELATED APPLICATIONS

This application is a continuation in part of U.S. application Ser. No. 12/763,799 filed Apr. 20, 2010. This application claims the benefit of U.S. Provisional Application No. 61/170,819, filed Apr. 20, 2009. This application is also a continuation-in-part of International Application No. PCT/US2009/039737, filed Apr. 7, 2009, which claims the benefit of U.S. Provisional Application No. 61/043,514, filed Apr. 9, 2008.

### TECHNICAL FIELD

The present invention relates generally to electrodes including fullerene structures produced via Carbo Thermal Carbide Conversion. Preferably the fullerene structures are substantially homogeneous and of high edge plane character and without transition metal impurities that interfere with the ability of the electrode to transfer electrons or detect an analyte. The invention also relates to enzyme-modified electrodes that, in one embodiment, are useful as sensors for nitrate or for power generation and storage using nitrate ions.

### BACKGROUND

Carbon nanotubes (CNTs) belong to a class of carbon allotropes, commonly referred to as fullerenes, which also includes nano-onions, horns, tubes, rods, wires, cones, dots, whiskers, filaments, nano-diamond, and graphene sheets. CNTs include an end cap which has properties similar to edge plane graphite and sidewalls which have properties similar to basal plane graphite. Smaller diameter tubes are generally more active, chemically and electrochemically, than larger diameter tubes. They have large pyramidalization angles and more pi bond separation, which eases access to mobile electrons. It has been reported that rates of electron transfer to or from edge plane graphite can be up to at least 100,000 times faster compared to electron transfer rates to or from basal plane graphite. Raman Spectroscopy in conjunction with Electron Microscopy and Thermal Gravimetric Analysis (TGA) have been used to quantitatively differentiate fullerene materials with high edge plane (low basal plane) content from those of high basal plane (low edge plane) content.

Raman spectra of CNTs and their related structures provide information regarding chirality, electronic conductivity, physical dimensions, defect or disorder content, type, and electronic structure. Of particular interest in cylindrical and tubular nanostructured crystalline carbon such as Solid Carbon Nano-Rods (SCNRs) and CNTs are: radial breathing mode (RBM) vibrations, typically 100 to 400 cm⁻¹ which are often used to determine diameters of CNTs and verify the presence of tubular structures such as concentric rings of CNTs and SCNRs; “G” band vibrations (and its components), typically around 1580 cm⁻¹, indicating in plane vibrations of the graphitic sheets; “D” band vibrations—often termed “defect band”, typically around 1350 cm⁻¹, indicating disruptions in the sp² bonds and the presence of non sp² carbon; and “G*” band vibrations, typically around 2650 cm⁻¹, which are second harmonics of the G band transition. Fullerenes exhibit a disorder induced D band due to loss of transitional symmetry. Sources of the D band include: sidewall defects, amorphous carbon impurities, bending, and loss of 1-dimensionality. The intensity of the “G*” band is much more unequivocally related to disruptions in sp² bonding in the basal plane; and thus, can be more directly associated with increased crystalline defects. Accordingly, the “G*” band is associated with enhanced electron transfer capabilities. Consequently, Raman spectroscopy can be used as a definitive tool to differentiate various carbon crystalline structures, which includes amorphous carbon impurities as well as side wall defects.

The G band present in fullerenes, and specifically cylindrical fullerenes has been associated with the nature of the graphene sheet(s) which form the structure. In cylindrical fullerene structures, the G band is comprised of at least two individual peaks. These two peaks, in a sufficiently homogeneous material in good resonance, give insight into the chirality, and thus conductivity of the fullerene. For example, in semiconducting SWCNTs, the low frequency G band constituent (at around 1570 cm⁻¹) typically is lower than the high frequency component (at around 1590 cm⁻¹). This relationship is particulary useful in determining the chirality for CNTs, which in turn gives insight into the electrical conductivity.

Thermal Gravimetric Analysis is a commonly used analytical technique that allows insight into the amorphous carbon content of many crystalline carbon materials. Amorphous or non-crystalline carbon typically oxidizes (in air) starting at about 200° C., where as crystalline carbon oxidizes between about 400 to 600° C., depending on size, chirality and defect rate. Amorphous carbon typically displays poor electrode properties, approximating basal plane HOPG performance. Thus it is valuable to be able to produce fullerene based electrodes with minimal amorphous carbon content for maximum performance.

High Resolution Transmission Electron Microscopy (HRTEM) can be used to directly confirm the presence or absence of amorphous carbon and to confirm the presence of physical structures indicated by the Raman spectra.

A common method for manufacturing fullerenes uses a catalyst such as a transition metal for growth of the carbon nanostructures via decomposition of a hydrocarbon. The transition metal may be iron cobalt, copper, aluminum, or nickel, for example, in the chemical vapor deposition (CVD) method. However, the seed metal at the CNT-substrate interface can degrade over time and/or corrode, which can lead to separation of the carbon nanostructure from its substrate. This separation can compromise the utility and/or the stability of a CNT electrode based on this structure. It can be difficult to produce fullerenes having a high enough aspect ratio to be considered 1-dimensional using these methods. Because this method involves “bottom-up” growth of CNTs, it results in largely aligned arrays which display high specific capacitance and sidewalls not favorable for electron transfer.¹ Finally, these methods can result in the formation of a non-homogeneous population of carbon structures a fairly high proportion of which are not fullerenes or nano-crystalline in nature such as carbon black and amorphous carbon. ¹ Herein, un-aligned or non-aligned arrays are referred to as being 3-dimensional arrays whereas aligned arrays are referred to as being 2-dimensional arrays.

Enzyme electrodes are used widely in environmental and medical applications. In an enzyme electrode, electrons are transferred (directly or indirectly) from or to the electrode and then to or from a redox group on the enzyme. The redox group cycles between oxidized and reduced states as the enzyme catalyzes the conversion of a specific substrate(s) to product(s). Measuring the concentration of specific enzyme substrates present can be accomplished by measuring the flow of electrons either directly or indirectly to or from the electrode. This electron transfer is indirect if it depends upon a so called mediator (natural or synthetic) that shuttles the electrons to or from the electrode and to or from the enzyme. In some cases this mediator can be tethered to the enzyme. Direct electron transfer (DET), of electrons between a solid, conductive substrate and a macromolecular protein, or complex assemblage of proteins, that acts catalytically upon a small molecule target, has been studied for some time. In some cases, DET is said to occur when electrons are transported between the electrode and the enzyme by an intermediary shuttle moiety, or electron mediator. The use of electron mediators to facilitate electron transfer is taught in Ameyama, M. (1982) Meth. of Enzymology, vol. 89 part D, pp. 20-29, Kinnear, K. and Monbouquette, H. (1997) Anal. Chem. Vol. 69(9), pp. 1771-1775, and U.S. Pat. No. 5,298,144 to Spokane. Ameyama illustrates the transfer of electrons from FDH (fructose dehydrogenase) via a ferrocyanide/ferricyanide couple, a common electron accepting mediator acting as a soluble electron mediator, to a collector electrode Kinnear and Monbouquette illustrate the transfer of electrons from FDH to a collector electrode via an electron mediator Coenzyme Q6 (also known as Ubiquinone-6) by a quinone-quinol coupling. According to U.S. Pat. No. 5,298,144 FDH is immobilizable within a mediator-filled polymer upon a vitreous [glassy]carbon electrode. The mediator is a bipyridyl complex of the osmium²⁺/osmium⁺³ redox couple mediator.

There is a need for an electrode including fullerene structures with relatively high electron transfer rates that can accomplish DET without an intermediary shuttle moiety or electron mediator. There is also a need for an electrode including fullerene structures with relatively high electron transfer rates that can be effectively used in voltammetric and/or electrochemical applications.

### SUMMARY

In accordance with one embodiment of the invention, an active electrode structure is provided that includes fullerenes produced by metal catalyst free conversion (e.g. Carbo-Thermal Carbide Conversion, described below) from a conductive carbide. In another embodiment, an electrode is provided that includes a fullerene covalently bonded to a conductive carbide, where the fullerene is an aligned or non-aligned array formed without a metal catalyst. The fullerene is included in an active electrode structure of the electrode that is characterized by a cyclic voltammogram (CV) peak separation of less than about 150 mV (at a scan rate of 5 mV/s in a 4 mM ferricyanide, 1M KCl salt solution). “Peak separation” refers to the separation in mVs between peak currents obtained for the reduction and oxidation of ferrocyanide/ferricyanide. In other embodiments, the peak separation may be less than about 100 mV, more particularly less than about 75 mV, and still more particularly less than about 65 mV, down to about 59.1 mV (i.e., the theoretical limit). With reference to the aforementioned peak separation, those skilled in the art will recognize that these peak separations are reported for the conductive carbide with the fullerene covalently bonded thereto, i.e., after the Carbo-Thermal Carbide Conversion process, independent of any other conductivity affecting features. The fullerenes may include about 50% or less non-crystalline carbon and about 5% or less of a transition metal that interferes with the ability of the active electrode structure to transfer electrons or detect an analyte.

Examination of the active electrode structure or the electrode having an active electrode structure shows that the active electrode structure comprises an unaligned array of conductive and crystalline carbon nanostructures with high edge plane content. In an embodiment that includes an electrode substrate, the crystalline carbon nanostructures are directly connected to the electrode substrate, preferably with covalent bonds.

“Active electrode structure” as used herein means the portion of the electrode which is in contact with the test solution and is capable of participating in electron transfer reactions with redox active species in the test solution.

Connecting an electrical lead to the substrate provides an electrode that can be used for energy production and storage, and chemical and biological sensing. The carbon nanostructures are fullerenes in one embodiment, still more specifically, CNTs, and still more specifically SCNRs. SCNRs are a specific and distinct subset of carbon nanotubes that can be produced via a Carbo-Thermal Carbide Conversion (CTCC) process described below. An analytical method indicating potential edge plane character is the Raman spectroscopy of the material. This nanocarbon material exibits low D band intensities using a 514 nm excitation laser as compared with that of other commercial materials, such as MWCNTs. This is largely due to low amporphous carbon content. When a 785 nm laser is used, side wall defects and internal strain, or kinks, become the major source of D band intensities, while a major source of the G* band is in strain or kinks. Thus, the G:G* ratio is small compared with other commercially available materials, indicating a high degree of strain in the SCNR structures. The G band itself provides insight into the homogeneity and electrical conductivity of the material. In summary, a 514 nm and 785 nm excitation laser when used in concert provide insight into the structure and purity of fullerenes.

The use of fullerenes and particularly SCNRs as disclosed herein are believed to enhance the performance of electrodes. Specifically, unaligned arrays of SCNRs or entangled bundles of SCNRs can be formed that provide superior voltammetric electrodes as contrasted with electrodes having aligned arrays of CNTs or SCNRs. This is believed to be due in part to the much higher specific capacitance associated with electrodes incorporating aligned arrays. Active electrode structures made up of unaligned arrays of entangled bundles of SCNRs, have high edge plane character and exhibit much higher electrochemical activity per unit surface area, than do active electrode structures composed of aligned arrays. This is believed to be due to the large number of kinks or “defects” present within individual SCNRs in the entangled bundles that are present on the surface of such electrodes. These “defects” are believed to result in higher edge plane character that provide sites at which electron transfer can occur more readily than other regions approximating basal plane HOPG, such as CNT sidewalls. The number of these sites per unit surface area is much greater in these nonaligned arrays than the number of sites present with aligned arrays. It is further reported, that in the case where the individual SCNRs are single walled (SW) and of relatively small diameter (about 0.5 to 0.7 nm), electron transfer can also occur at a higher rate across the sidewalls, as compared with larger diameter SCNRs (single walled or multiwalled), due to greater π-electron cloud separation and strained pyramidization resulting from smaller diameter. The small dimensions of the SCNRs within unaligned arrays and the presence of nanoscale surface features (kinks) are also believed to be important in achieving DET to redox enzymes. It is believed that the ends of SCNRs and/or kinks are small enough in scale to actually protrude into the redox/active site of the enzyme and directly interact with electron transferring groups.

In one embodiment, the fullerene structures are produced using the method disclosed in International Application PCT/US2009/039737 (“the '737 App”), which is incorporated herein by reference in its entirety. As noted before, this method does not require the use of a catalyst particle to form carbon nanostructures in large quantities and higher production rates than possible with previous technology. In this method a reactive gas is introduced into a chamber, such as a graphite reactor, containing a carbide substrate such as silicon carbide, and byproducts are actively scavenged from the reactor. By decomposing the carbide substrate with a reactive gas (or admixture of inert and reactive gases), the carbide is converted to largely crystalline carbon nanostructures. This process is described in more detail below. Other carbides include boron carbide, aluminum carbide, titanium carbide, and zirconium carbide. In one embodiment, the carbide substrate includes more than one carbide material.

One aspect of the invention is an electrode that includes an electrode substrate and an electrical lead connected to the electrode substrate, wherein the electrode substrate is formed from or coated with a metal or metalloid carbide on at least a portion of the surface of the electrode substrate being converted to carbon in the absence of a catalyst to produce crystalline carbon nanostructures that are joined to the surface of the electrode substrate. The junction between the electrode substrate and the crystalline carbon nanostructures is characterized in that it does not contain a catalyst or other contaminant which may destructively interfere with electrode performance. This should not be construed to exclude from the scope of the claims electrodes to which other metals or substances are added to the electrode substrate to enhance performance of the electrode.

In one embodiment, the substrate has an ohmic resistance of less than about 5000 Ω/sq. In other embodiments, the ohmic resistance is less than about 1000 Ω/sq, still more particularly less than about 100 Ω/sq, still more particularly less than about 10 Ω/sq, still more particularly less than about 1 Ω/sq, and still more particularly less than about 0.1 Ω/sq.

In another aspect, an active electrode substrate is provided that includes fullerenes produced by conversion from a conductive carbide. The conversion includes oxidation of the carbon in the carbide and reactively removing a metal or metalloid component from the carbide to facilitate fullerene growth. The carbide may be at least a 70% crystalline carbide content, more preferably at least a 99% crystalline carbide content. In a further embodiment, the carbide substrate may be modified to enhance its electrical conductivity, for example, it may be doped with nitrogen or contain carbon.

In one embodiment, the crystalline carbon nanostructures on the modified surface of the electrode substrate extend essentially randomly from the surface. The nanostructures may be nanorods and/or nanotubes and/or bundles of these structures. In one embodiment, the nanostructures may be characterized by a ratio of D band Raman signature to G band Raman signature at a 785 nm excitation of about 1:2 to about 2:1. Because D band intensity can be attributed to more than one source, redundant techniques are used to avoid experimental misinterpretation of D band intensity. Preferably, High Resolution Transmission Electron Microscopy (HRTEM) and/or TGA are used to verify amorphous carbon or edge effects are not a predominant source of the D band intensity. An electrochemical technique such as Cyclic Voltammetry (CV) can be used to characterize the carbon nanostructures relative to electron transfer rate. In another embodiment, the electrode produced has a stable and reproducible background current in aqueous and non aqueous solvents indicating the absence of destructive impurities. Transition metal contamination significantly alters the electrochemical background window of fullerene electrodes due to uncontrolled oxidation and/or reduction of the metal contamination. It is believed that this results in a transient background which may significantly alter the perceived response of the electrode or contributed destructively to its performance.

The nanostructures described above may be attached to a current collector such as platinum, various carbides or glassy carbon. In one embodiment, the crystalline carbon nanostructures are present as a layer on the surface of the current collector. The electrode substrate may be planar (e.g., a disk) or non planar (e.g., a foam or fiber). In another embodiment, the crystalline nanocarbon is produced by substantially complete conversion of a carbide(s) and the resulting free standing crystalline nanocarbon can be applied as a paste. These electrodes may find applications in the similar field of chemical/biological sensors, batteries, and fuel cells. The DET embodiment described below is particularly applicable to electrochemical capacitors, bio-batteries, bio-fuel cells, and bio-sensors.

Another aspect of the invention is an electrode as described above that also includes one or more proteins. The protein may be an enzyme, preferably an enzyme that includes an electron accepting or donating group that forms a direct electrical connection (DET) to the crystalline carbon nanostructure. In one embodiment, the electron accepting or donating group may be a heme, a pyrroloquinoline quinone, a flavin adenine dinucleotide, a flavin mononucleotide, a copper atom, a magnesium atom, a molybdenum atom, a zinc atom, or an iron-sulfur cluster. In one embodiment, the electron accepting or donating group is a heme and the enzyme is a nitrate reductase. In another embodiment, the nitrate reductase having a heme is a simplified eukaryotic nitrate reductase described in U.S. Pat. No. 7,262,038, incorporated herein by reference in its entirety.

In another embodiment, the enzyme electrode does not include an electron mediator such as ferricyanide, ferrocenes, osmium or ruthenium bipyridyl complexes, triphenylmethane dyes, and viologen compounds to transfer electrons from the protein to the electrode substrate. In addition to the enzyme, other coatings may be present on the electrode.

Another aspect of the invention is a sensor for detecting nitrate that includes the electrode described above, with a SCNR modified carbide on the surface of the electrode substrate, and a nitrate reductase enzyme having an electron accepting or donating group directly electrically connecting the nitrate reductase enzyme to the crystalline carbon nanostructures. In one embodiment, the electron accepting or donating group is a heme and the nitrate reductase is the engineered recombinant eukaryotic nitrate reductase mentioned above.

Another aspect of the invention is a method of making an electrode for a biosensor. The method includes 1) providing an electrode substrate comprising a crystalline carbon nanostructures joined to the surface of the current collector, 2) connecting an electrical lead to the electrode substrate, 3) providing an enzyme in solution, and 4) applying the enzyme in solution to the crystalline carbon nanostructures of the electrode substrate. The enzyme adsorbs, preferably chemisorbs, onto the crystalline carbon nanostructures joined to the surface of the substrate. This adsorption provides the enzyme with a direct electrical connection to the crystalline carbon nanostructures such that electrons can pass to or from the crystalline carbon nanostructures and to or from the enzyme. The junction between the electrode substrate and the crystalline carbon nanostructure is characterized in that it does not contain metal catalyst atoms detrimental to the performance of the electrode.

### BRIEF DESCRIPTION OF THE DRAWINGS

FIG. 1 is a Transmission Electron Micrograph image of SCNR clusters.

FIG. 2 is a Transmission Electron Micrograph of a SCNR cluster.

FIG. 3 is a Transmission Electron Micrograph of a SCNR whisker.

FIG. 4 is a High Magnification Electron Micrograph of a SCNR whisker.

FIG. 5 is a side perspective view of one embodiment of an electrode.

FIG. 6 is a cross-sectional view of the electrode of FIG. 5.

FIG. 7 is an enlarged perspective side view of the substrate in the electrode of FIG. 5 showing its reactively modified surface.

FIG. 8 is a side perspective view, in cross-section, of an embodiment of an electrode.

FIG. 9 is a side perspective view of an embodiment of an electrode.

FIG. 10 is a cross-sectional view of the electrode of FIG. 9.

FIG. 11 is a Raman Spectrum of the High Edge Plane Fullerene structures of Example 1.

FIG. 12 is a Background Cyclic Voltammogram of SCNR Modified Conductive SiC Disk Electrode of Example 2.1.

FIG. 13 is a Cyclic Voltammogram of Ferri/Ferrocyanide at a SCNR Modified Conductive SiC Disk Electrode of Example 2.2.

FIGS. 14A-14B are an Anodic Stripping Voltammogram at a SCNR Modified Conductive SiC Disk Electrode of Example 2.3 and a corresponding calibration curve.

FIG. 15 is a Background CV of SCNR Modified Open Cell Foam Electrode of Example 3.1.

FIG. 16 includes Cyclic Voltammograms of Ferri/Ferrocyanide on SCNR Modified Open Cell Foam Electrode of Example 3.2 with Varying Scan Rates.

FIG. 17 is a Cyclic Voltammogram response of an Enzyme Modified—Open Cell Foam Electrode of Example 3.3 to Nitrate.

FIG. 18 is a Cyclic Voltammogram showing background Cyclic Voltammogram Scans on Various Carbon Paste Electrode Materials of Example 4.1.

FIG. 19 is the Cyclic Voltammogram of FIG. 19 on an expanded scale.

FIG. 20 is a Cyclic Voltammogram of MWCNTs (A) and SCNR Nanoclusters (B) in the Presence of 1 mM Hydrazine of Example 4.2.

FIG. 21 is a Cyclic Voltammogram of Ferri/Ferrocyanide on an Electrode Fabricated with Increasing SCNR Loading at 10 mV/s scan rate of Example 4.3.

FIG. 22 is a TGA Measurement Performed on a Sample Consisting of SCNR Whiskers of Example 4.4.

### DESCRIPTION OF THE INVENTION

The following detailed description will illustrate the general principles of the invention, examples of which are additionally illustrated in the accompanying drawings. In the drawings, like reference numbers indicate identical or functionally similar elements.

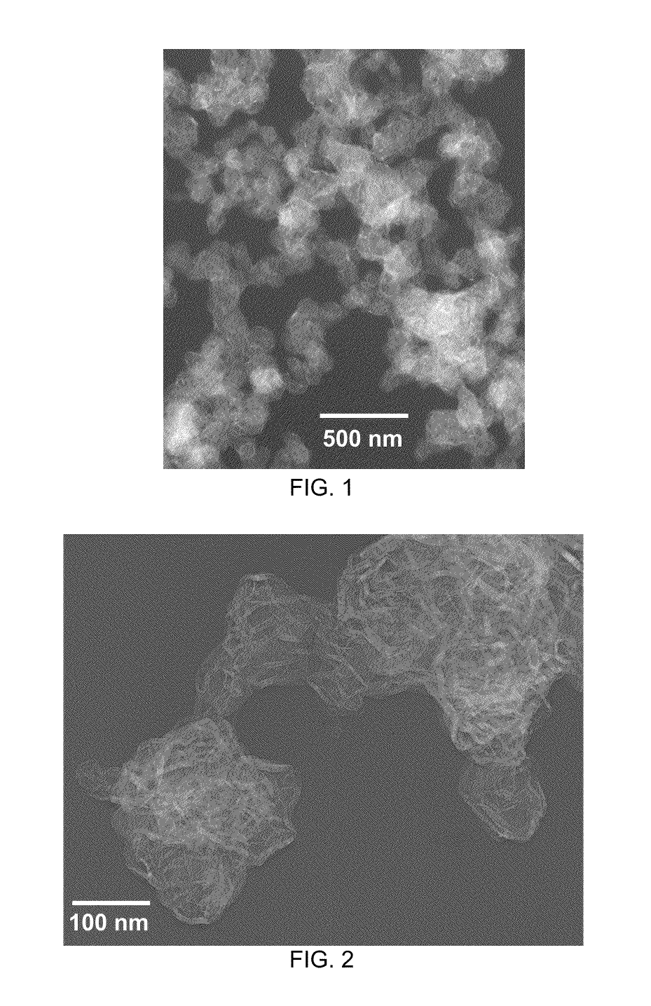

Referring to FIGS. 1-2, TEM images of fullerene structures, in particular SCNRs and SCNR clusters, are shown. SCNR clusters are free standing bundles of SCNRs without covalent attachment to carbide. Similarly, SCNR whiskers are clusters with largely cylindrical morphology with an aspect ratio greater than 1. FIG. 1 is a low magnification TEM image showing the geometry of the SCNR cluster structures and FIG. 2 shows the same clusters at higher magnification. At this magnification, the SCNR structures within the SCNR clusters are shown. These fullerenes may be formed by known methods, including the method described in the '737 App. In one embodiment, the fullerenes are free of a catalyst, specifically a metal catalyst or redox catalyst. The fullerenes may be free standing bulk material that can be combined with other substances, (e.g., a binder or filler) for various applications, for example as a paste electrode. In another embodiment, the fullerenes may be joined to a substrate. In one embodiment, the fullerenes are formed by converting a carbide to fullerenes. The reaction that modifies the surface of the carbide may include removal of the metal or metalloid of the carbide as a gaseous by-product. When the fullerenes are formed by conversion of the carbide in this manner it is believed that the fullerenes are covalently bonded to the remaining unreacted portion of the carbide substrate.

As described in the '737 App, one process that may be carried out to form the fullerenes includes processing a carbon containing material in a graphite hot zone reactor. The process may include the preliminary step of cleaning the surface of the carbon containing material, for example, using high vapor pressure organic solvents (such as acetone, alcohol, or hexanes), plasma etching, acid etching, or similar means. When the substrate is a metal/metalloid carbide (or mixture of carbides) the reaction is generally represented as:

Reactive Gas+Metal/Metalloid Carbide→Metal/Metalloid Byproduct+Carbon

wherein the carbon product is preferably a crystalline carbon nanostructure, such as the SCNR clusters in FIGS. 1-2.

In one embodiment, inert gases, typically N₂ and/or noble gases may be used in combination with the reactive gas to adjust the reaction and the quality of the product nanostructures. Suitable reactive gases include air, H₂O, NH₃, CₓO_{y}, O₂, NOₓ, H₂, and admixtures of these gases. Admixtures of halogens and other reactive gases may also be used to produce aligned and non aligned arrays. Further suitable reactive gases may include only halogens, and admixtures of halogens to produce non aligned arrays and bulk fullerenes. Additional reactive gases may be used particularly organometallics, perchlorates, and peroxides. The reactive gas is selected based on the desired chemical reaction and the substrate involved. It is preferred that 1) the metallic or metalloid (e.g., Si) component react to form a gaseous compound at the processing temperature, 2) the reactive gas does not passivate the carbide surface, 3) the reactive gas does not oxidize or otherwise degrade the crystalline carbon nanostructure product, and 4) the gaseous by-product(s) of its reaction with the carbide do not competitively react with the carbon product.

In one embodiment, SiC is reacted with air in a graphite reactor. In one embodiment, reactive carbon oxides are produced in situ via reaction of oxygen and the graphite components of the reactor. Water is present in the graphite reactor, typically in the air bleed, as vapor to participate in the reaction of the SiC. The relevant reactions of SiC that occur within a graphite reactor zone at the appropriate temperature and in the presence of the appropriate reactive gases (oxygen and water) are believed to be:

SiC+CO→2C+SiO and, (1)

SiC+H₂O→SiO+C+H₂

The substrate for the electrode may be any carbide ceramic, such as silicon carbide, boron carbide, aluminum carbide, iron carbide, chrome carbide, or zirconium carbide in single crystal, polycrystalline or amorphous states. The substrate may be a mixture of carbides. The carbide may be present as a coating applied to another inert substrate by any number of synthetic methods/processes including vapor deposition, pulsed laser deposition or any other process known for application of carbides. Alternatively, pure carbide materials including powders and monolithic carbides can be utilized. The crystallinity and morphology (crystal orientation) surface profile of the substrate affects the resulting nanostructure, for example by templating the carbon in a defined and controlled way. In one embodiment, a CVD grown conductive randomly oriented polycrystalline carbide is used to produce nonaligned arrays of fullerenes. In one embodiment, the carbide has at least a 50% crystalline carbide content, preferably at least a 70% crystalline carbide content, and more preferably at least a 99% crystalline carbide content.

In one embodiment, the carbide includes a conductive carbide. In one embodiment, the conductive carbide may be n-doped. In another embodiment it may be natively conductive such as boron carbide. In one embodiment, the conductive carbide, prior to the Carbo-Thermal Carbide Conversion, has an ohmic resistance of less than about 5000 Ω/sq. In another embodiment, it has an ohmic resistance of less than about 1000 Ω/sq. In another embodiment, it has an ohmic resistance of less than about 100 Ω/sq. In another embodiment, it has an ohmic resistance of less than about 10 Ω/sq. In another embodiment, it has an ohmic resistance of less than about 1/10 Ω/sq. In another embodiment, the conductive carbide has an ohmic resistance of less than about 1/10 Ω/sq.

Fullerenes of interest for application in an electrode and other applications involving the transfer of electrons are electrochemically clean, have small diameters, and are believed to have increased edge plane character due to the number of dislocations in the π bonding on the nanostructures' wall, referred to as “kinks,” which are available for electron transfer. The diameters of the fullerenes may be about 0.3 nm to about 40 nm. In one embodiment, the fullerenes include carbon nanotube having diameters of about 0.3 nm to about 40 nm. In another embodiment, the fullerenes include carbon nanorods having diameters of about 0.3 nm to about 40 nm. The fullerenes may also include both carbon nanotubes and carbon nanorods having such diameters.

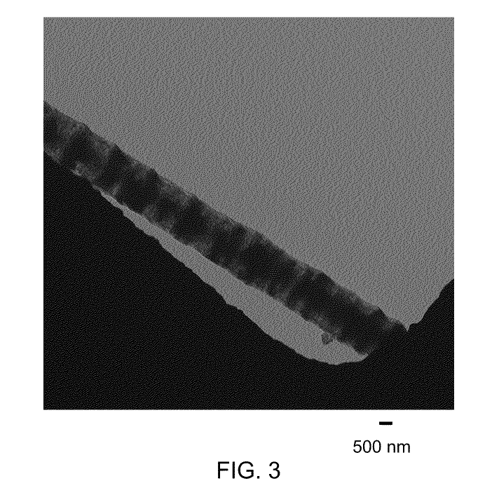

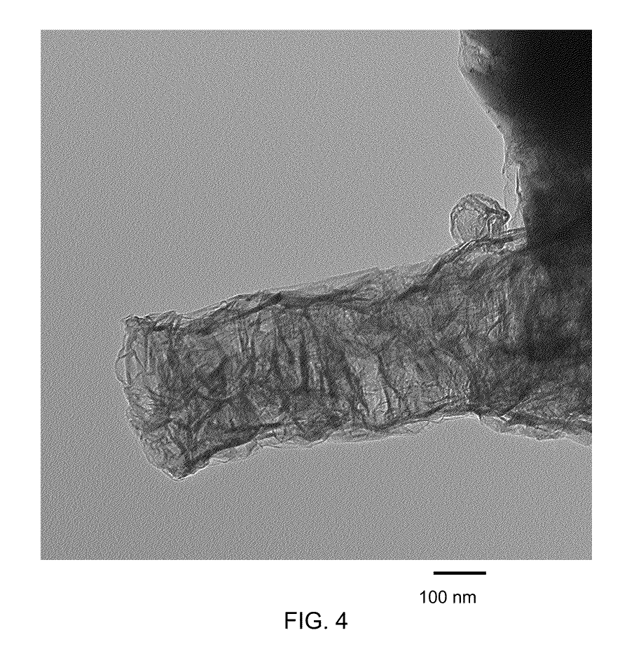

The “kinked” carbon nanostructures are believed to have a high surface area for electron transfer. FIG. 3 shows a high aspect ratio SCNR Cluster and FIG. 4 shows a SCNR structure within the high aspect ratio cluster of FIG. 3. FIG. 4 shows the hyper-extended surface area, the “kinks,” characteristic of the clusters. In one embodiment, the degree of strain (due to “kinks”) or edge effects may be determined using Raman Spectrometry (in conjunction with other analytical techniques) and comparing the D band intensity to the G band intensity with appropriate excitation frequencies, for example 514 nm (green) and 785 nm (red). D band intensity has been found to correlate to carbon nanostructure defects such as sidewall defects, finite dimensions, and mechanical stresses (kinks) in crystalline carbon nanostructures. While the G* band intensity is more related to defects in the crystal structure alone. The D band to G band ratio may be about 1:15 to about 2:1 at a 514 nm excitation. The D band to G band ratio may be about 1:10 to about 2:1 at a 785 nm excitation. The G band to G* band ratio may be about 10:1 to about 1:5 at a 514 nm excitation. The G band to G* band ratio may be about 12:1 to about 1:5 at a 785 nm excitation. While Raman spectroscopy may lend insight into the edge plane content, it is possible to convolute data obtained with contaminants resulting from manufacture, for example amorphous carbon and graphene encapsulated catalyst from CVD growth. Thus, without supporting evidence these contaminants are not present, Raman spectroscopy may not correlate with edge plane content. One technique for providing evidence that contaminants are or are not present is TGA.

The active electrode structure may also be described by its peak separation as determined from a cyclic voltammogram from a cyclic voltammetry experiment performed at a scan rate of 5 mV/s in a 4 mM ferricyanide, 1M KCl solution. The salt solution does not have to be KCl, and may instead be NaCl, or other equivalent salts. An active electrode structure that includes fullerenes grown on or from a conductive carbide by the methods described above have a peak separation of less than about 150 mV. “Peak separation” refers to the separation in mVs between peak currents obtained for the reduction and oxidation of ferrocyanide/ferricyanide. In one embodiment, the active electrode structure's peak separation is less than about 100 mV. In another embodiment, the active electrode structure's peak separation is less than about 75 mV. In another embodiment, the active electrode structure's peak separation is less than about 65 mV. In another embodiment, the active electrode structure's peak separation is about 59.1 mV, the theoretical (e.g., Nernstian) limit.

In one embodiment, the material comprising the active electrode structure is also characterized in that it has a reduced content of non-crystalline carbon. In one embodiment, the material is about 70% or more fullerene and includes about 30% or less non-crystalline carbon as determined by TGA (in air) below 500° C. Non-crystalline carbon typically oxidizes during TGA at temperatures of around 200° C. compared to crystalline carbon which does not oxidize until higher temperatures, between 400-600° C., are reached. In another embodiment, the material comprising the active electrode structure is about 50% or more fullerene and includes about 50% or less non-crystalline carbon. In another embodiment, the material comprising the active electrode structure includes about 90% or more fullerene and about 10% or less non-crystalline carbon, more preferably about 95% fullerene and about 5% or less non-crystalline carbon. In another embodiment, the material comprising the active electrode structure includes about 99% fullerene and about 1% or less non-crystallin carbon, more preferably about 99.9% fullerene and 0.1% or less non-crystalline carbon.

The material comprising the active electrode structure is further characterized in that it is essentially free of interfering additives or contaminants. In one embodiment, the fullerenes include about 5% or less of substances that degrade or interfere with the performance of the electrode. In another embodiment, the fullerenes include about 2% or less of substances that degrade or interfere with the performance of the electrode or even 1 or less of such substances. Substances that can degrade or interfere with the performance of the electrode include transition metals such as those that are easily oxidized or reduced, for example, Fe, Ni, Co, and Cu. In one embodiment, the material comprising the active electrode structure includes about 5% or less of a transition metal, more preferably about 2% or less of a transition metal, and even more preferably 1% or less of a transition metal. Typically, these metals are left over from the process that formed the fullerenes, but is not limited thereto, in particular, they are left over from the use of a metal catalyst for catalyzing the growth of the fullerenes. The presence of the metal left over from the metal catalyst may be included in the active electrode structure as less than about 500 ppm, more preferably as less than about 1 ppm.

In one embodiment, the active electrode structure may include one or more metals, preferably a transition metal, that enhance the active electrode structure's performance. For example, the active electrode structure may include a “noble metal” such as Ag, Pt, Rh, Ir, Pd, or combinations thereof used in an amount that enhances the transfer of electrons and/or the detection of an analyte. In one embodiment, the fullerene portion of the active electrode structure is modified to include a transition metal to enhance the active electrode structure's performance; however, the transition metal was not applied as a metal catalyst to initiate the growth of the fullerene.

The material comprising the active electrode structure may also include a binder, a filler, or both. Examples of binders and/or fillers include epoxy, paraffin and polypyrrole. In one embodiment, the material comprising an active electrode structure includes non-crystalline carbon content, is essentially free of interfering additives or contaminants as described above and is an unaligned, entangled (3-dimensional array) of fullerenes with HEPC. In an alternate embodiment, such fullerenes may be an aligned 2-dimentsional array. 2-dimensional arrays can be etched to abrade the surface thereby creating a 3-dimensional array.

In one embodiment, the active electrode structure is connected by the fullerene to an underlying portion of unconverted substrate (i.e., a portion that was not converted to fullerene). In one embodiment, the fullerene is connected to the underlying portion of the substrate by covalent bonds.

The material comprising the active electrode structure may include fullerenes having the above described characteristics having proteins or enzymes coupled to the fullerenes to provide an improved/enhanced enzyme electrode structures. Due to the unique 3-dimensional shape, HEPC, purity, and homogeneity of the fullerenes, the fullerenes are uniquely suited for fabrication of enzyme modified electrodes incorporating DET, including printed electrodes and layer by layer electrode production. Representative examples of useful proteins include non-limiting examples of enzymes include glucose oxidase, nitrate reductase, horseradish peroxidase, laccase, and others. In one embodiment, the enzyme is a nitrate reductase. In another embodiment, the nitrate reductase has a heme, and is preferably a simplified eukaryotic nitrate reductase, also referred to herein as an engineered recombinant eukaryotic nitrate reductase. The simplified eukaryotic nitrate reductase is preferably the nitrate reductase (S—NaR1) or (S—NaR2) disclosed in U.S. Pat. No. 7,262,038 to Campbell et al. The amount of enzyme coated onto the nanocarbon surface is preferably within the range of about 2 ng to about 500 ng per square millimeter of covered geometric surface area.

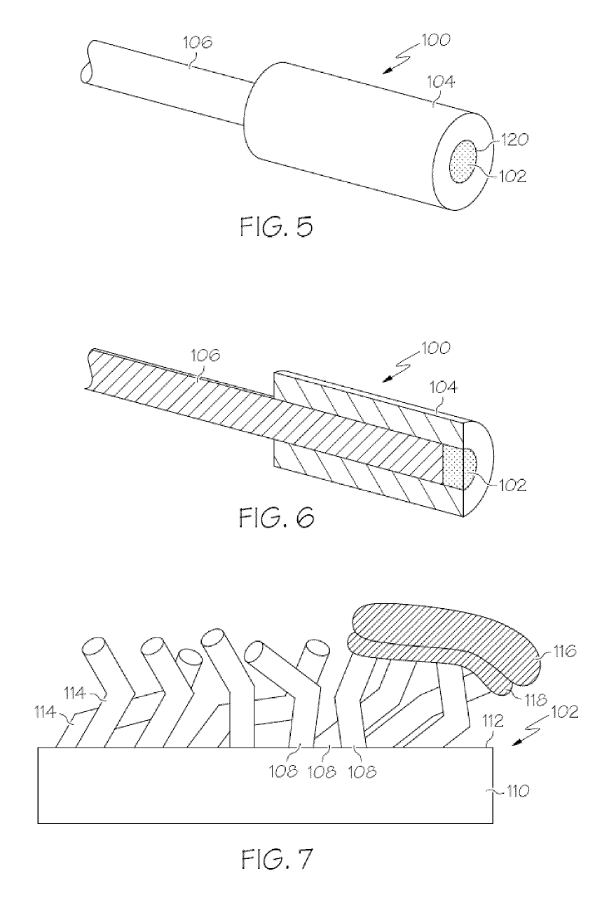

Referring now to FIGS. 5-7, in one embodiment, the electrode 100 includes an electrode substrate 102 having at least a portion of a surface 112 converted to elemental crystalline carbon nanostructures 114 joined to the surface of the electrode substrate, and an electrical lead 106 connected to the electrode substrate 102. In one embodiment, the junction 108 between the substrate and the crystalline carbon nanostructure is characterized in that it does not contain a metal catalyst. As seen in FIG. 7, the electrode substrate 102 includes the reacted surface 112 comprising the crystalline carbon nanostructure 114 and an unreacted base 110. Preferably the electrical lead 106 connects to the unreacted base 110 of the substrate. In one embodiment, the reacted surface 112 includes a protein 116 electrically connected to the crystalline carbon nanostructures 114 at the end opposite the junction 108 to the electrode substrate 102. The electrode substrate 102 may have substantially any geometry including having a planar or a non planar surface.

In another embodiment, the crystalline carbon nanostructures 114 may be free standing rather than connected to the unreacted base 110 of the electrode substrate 102. The free standing crystalline carbon nanostructures may be combined with a binder or a filler to adhere the crystalline carbon nanostructures to a current collector. In one embodiment, the crystalline carbon nanostructures are SCNRs.

In one embodiment, the electrode substrate is or is coated with a conductive carbide such as an n-doped silicon carbide. Such an electrode substrate is available from Morgan Technical Ceramics under the name Performance SiC or from ERG Materials and Aerospace Corporation under the name DUOCEL® ceramic foam. Doping the carbide has the effect of lowering the electrical resistivity inherent in the carbide. Minimizing ohmic losses is especially important in the design and construction of power generation and storage devices.

In one embodiment, the electrode substrate is a disk of silicon carbide, as shown in FIG. 7. A surface of the silicon carbide is illustrated as being modified with SCNRs. The nanostructures are preferably SCNR structures, and more preferably solid carbon nanorods (SCNR), arranged randomly on the electrode substrate to form a 3-dimensional array of fullerene structures. In one embodiment, the SCNR 3-dimensional array was formed by a process taught in the '737 App and resulted in SCNRs having generally uniform diameter.

As shown in FIGS. 5-6, the electrode 100 may include a housing 104, such as but not limited to a hollow, generally cylindrical member, enclosing a portion of the electrical lead 106 and a portion of the electrode substrate 102, in particular, enclosing the connection of the electrical lead to the electrode substrate. In one embodiment, the housing 104 may include a port 120 that provides access to the reactively modified surface 112 of the electrode substrate 102. The housing preferably is formed of a chemically inert and electricaly insulating material, for example but not limited to, glass, ceramic, cellulosic composites, polytetrafluoroethylene (PTFE), poly(methyl methacrylate) (PMMA), epoxy, polyethylene, polypropylene, acrylic, polyamide, polystyrene, acetal, PVC, ABS, PET, ETFE, ECTFE, PFA, FEP, PEEK, polyimide, polyetherimide (for example Ultem® polyetherimide), and polyphenyl sulfone (for example Radel® R polyphenyl sulfone). The housing 104 may be about 8 mm in outer diameter and about 15-30 mm in length.

The electrical lead 106 may be any suitable metal, preferably a metal wire. In one embodiment, the electrical lead is a copper 18 to 22 awg wire. In another embodiment, the electrical lead is a 0.8 to 1.3 mm solid brass rod.

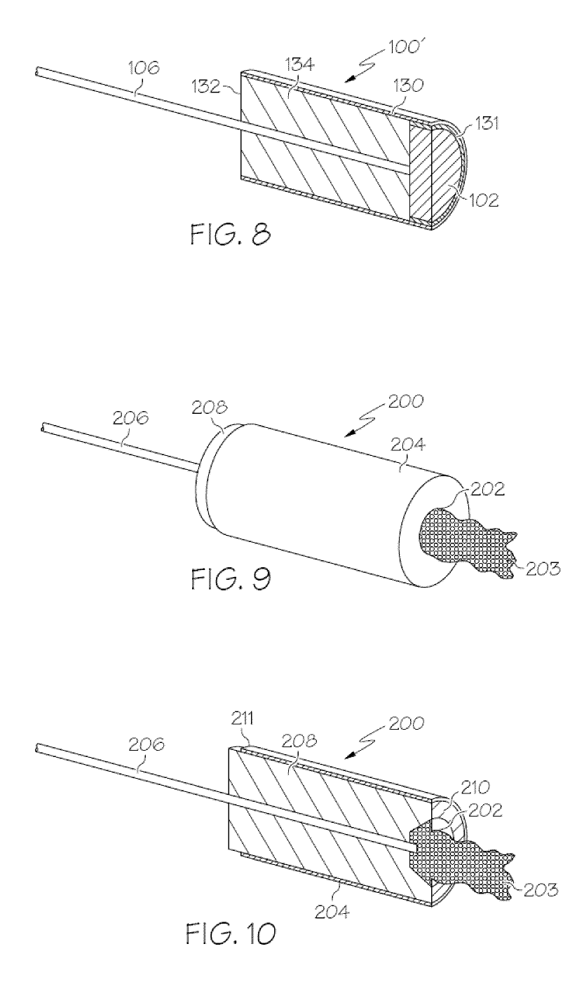

Referring to FIGS. 9-10, another embodiment of an electrode 200 is disclosed that includes a sponge 203, foam, or other porous material as the electrode substrate 202. Electrode 200 includes a hollow generally cylindrical housing 204 having a first end 210 with the electrode substrate 202 mounted therein. The electrode substrate 202 may have a portion of its reacted surface extending outside the housing 204 and an electrical lead 206 connected to the substrate and extending there from and from the housing 204. In one embodiment, the electrical lead may exit the housing 204 at its second end 211. The housing 204 may be filled with an electrically insulating material or inert polymer material 208 such as those discussed above. The foam may have a pore density of about 45 ppi to about 100 ppi.

Any of the electrodes describe above may be used to detect chemical or biological analyte(s) in a test solution or as an electrode with general electrochemical research utility. The electrode may include just the material comprised of free standing crystalline carbon nanostructures (SCNR clusters or whiskers) and binders and or fillers extending from a surface thereof and an electrical lead connected to an under lying current collector.

In one embodiment, the crystalline carbon nanostructures may be treated with a covalently-bound molecular grouping that has a particular affinity for a detectable species, for example, a covalently bound amino acid such as cysteine may enhance detection of heavy metal ions. A cysteine treatment is believed to enhance the detection of the heavy metals copper, silver, cadmium, mercury and lead by chelation in the manner as described by Morton et al. (Electroanalysis, 2009, vol. 21, no. 14, pp. 1597-1603), with possible additional affinity supplied by the heavy metal atom—cysteinyl sulfur affinities.

In another embodiment, any of the electrodes disclosed herein may be used to detect the presence and/or quantify an analyte that is electrochemically active (the analyte can undergo a redox reaction). The analyte may be identified by correlating the identity of the analyte to a signal indicative of the analyte's change in oxidation state. The signal may be a peak current detected as the electrode voltage is varied. In one embodiment, the electrode is placed into a test solution and the analyte is allowed to deposit on the fullerene structures of the electrode. The analyte may be collected on the fullerene structures by physisorption, chemisorption, intercalation, or deposition. Thereafter, the analyte is stripped from the fullerene structures by a known method, for example anodic, cathodic, or adsorptive stripping. The signal produced from stripping the analyte is then correlated to the identity and/or the amount of the analyte.

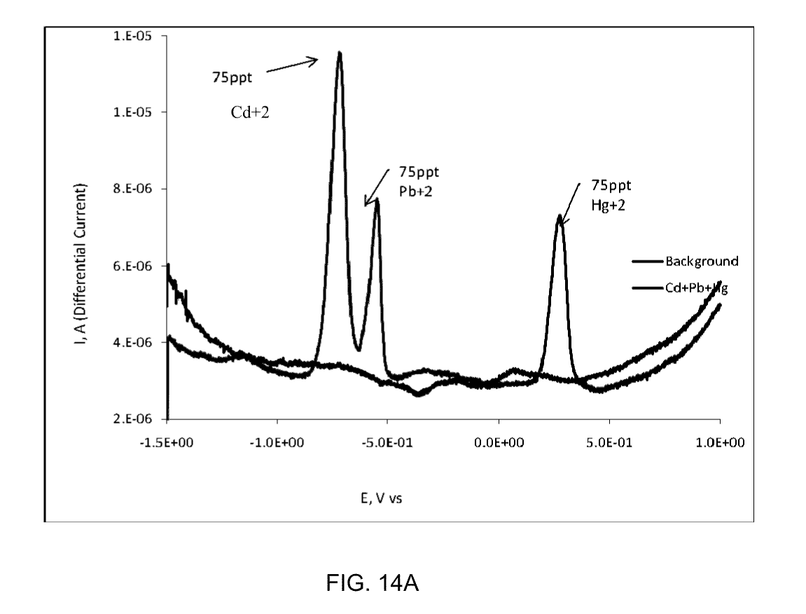

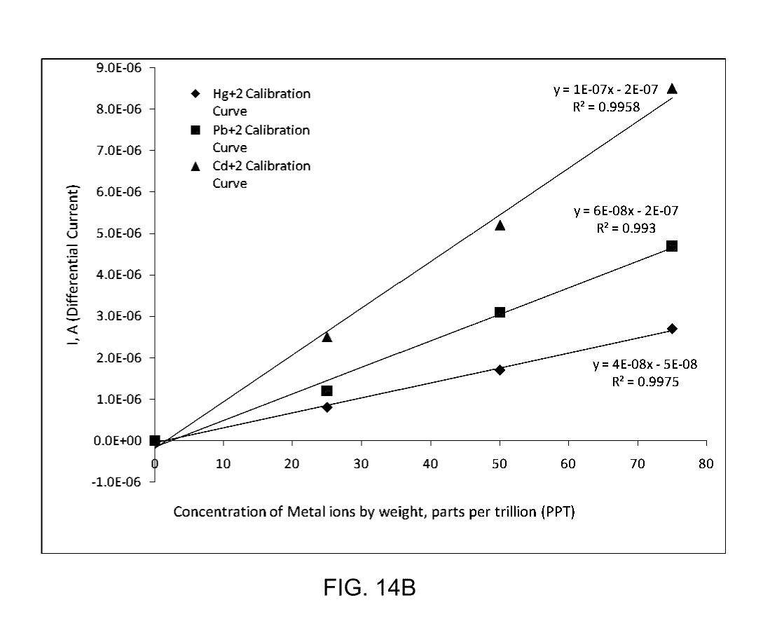

In one embodiment, an electrode including fullerene structures of a high edge plane character is placed in a test solution that contains one or more metal ions or metal complexes. The metal or metal complex ions deposit on the fullerene structures or on a coating adjacent to and in contact with the electrode surface and are thereafter stripped using a known anodic stripping technique. As each metal ion is stripped from the fullerene structures a peak corresponding to the change in oxidation state of the metal, generically represented by M⁰→M^{+x}, is measured and/or recorded. An example graph showing a background scan (before adding metal ions) and peaks for Cd⁺², Pb², and Hg⁺² (each metal ion added to a final concentration of 75 parts per trillion (ppt) into fresh river water) measured by anodic stripping is shown in FIG. 14A. From the peak, each metal may be identified, e.g., its identity is correlated to the peak position (voltage) and the quantity of each metal ion present can be determined from the peak height (current) or integrated peak current (charge). FIG. 14B shows a corresponding calibration curve for each of the three metals from 0 to 75 ppt also determined in fresh river water.

In another embodiment, an electrode like those described above additionally includes one or more proteins 116 (FIG. 7) connected to the carbon nanostructures 114. The protein 116 may be an enzyme and preferably an enzyme that includes an electron accepting or donating group that provides a direct electrical connection to the crystalline carbon nanostructure. FIG. 7 illustrates a reacted surface 112 of the electrode substrate 102 having a protein 116 electrically connected to a fullerene structure 114 at the end opposite the junction 108 to the substrate 102 via an electron accepting or donating group 118. Since the electron accepting or donating group directly electrically connects the enzyme to the nanostructure, an electron mediator may not be needed. Representative examples of the electron accepting or donating group 118 may be a heme, a pyrroloquinoline quinone, a flavin adenine dinucleotide, a copper ion, a magnesium ion, a zinc ion, or an iron-sulfur cluster. In one embodiment, the electron accepting or donating group is a heme.

The attachment of the enzyme to the fullerene structures can be achieved in a known manner, e.g., through chemisorption to chemically modified or unmodified fullerene structures, or via covalent attachment to modified or chemically functionalized fullerene structures. In one embodiment, the chemisorption of the enzyme includes diluting the enzyme in an aqueous solution, for example, a buffer solution, and soaking the fullerene structures in the solution. The soaking time may vary. The enzyme is preferably adsorbed in the presence of minimal buffer salts, such as 10 millimolar MOPS buffer, pH 6.8 in the absence of metal ions or chelators. Soaking times may be as short as 2 minutes or as long as 2 hours or longer. The temperature of deposition is preferably about 20° to 40° Celsius. The enzyme, like the fullerene structures, may also be modified or chemically functionalized before attachment of the enzymes to promote the intimate attachment of the enzyme to the carbon nanostructure.

Modification or chemical functionalization (through reactivity of the free electron sites) of the fullerene structures can be achieved with organic or inorganic reagents or materials. These reagents/materials typically include, but are not limited to: various chemical functionalization reagents, polymers (e.g., ion exchange resins and ionic polymers such as NAFION, polystyrene sulfonic acid, PVTAC, etc, and permeability selective resins), metallic nanoparticles of metals (e.g., gold, etc.), metal oxide particles (e.g., CaO, ZnO, etc.), ceramic particles (e.g., ferromagnetic beads, etc.), and ionic liquids (e.g., N-dimethylformamide, etc.). Another method of functionalizing the fullerene structures includes treating the reactively modified surface with plasma etching for varying degree of functionalization, which is controllable by selecting the process parameters, energy, and duration of treatment. For example, a low pressure oxygen plasma is used to partially oxidize the electrode surface to promote electron transfer in aqueous solution as well as improve enzyme attachment. Any of the electrodes disclosed herein may be incorporated into a chemical or biological sensor. In one embodiment, the sensor is for the detection of nitrate. Such a sensor includes one of the electrodes described above having a crystalline carbon nanostructure modified carbide as the electrode substrate and a nitrate reductase enzyme having an electron accepting or donating group electrically connecting the nitrate reductase enzyme to the crystalline carbon nanostructures. In one embodiment, the electron accepting or donating group is a heme and the nitrate reductase is a simplified eukaryotic nitrate reductase, such as the nitrate reductase S—NaR2 disclosed in U.S. Pat. No. 7,262,038.

### Example 1

A conductive (nitrogen n-doped, CVD grown) silicon carbide disk, available from Morgan Technical Ceramics (Hudson, N.H.) under the name Performance SiC, was placed in a graphite hot zone reactor and processed to form fullerene structures having high edge plane character on a surface of the disk. The fullerene structures were formed by Carbo Thermal Carbide Conversion.

Disks were placed into an all graphite hot zone vacuum reactor as received and the reactor evacuated to 1 Torr. Once the desired vacuum level was reached, the reactor was heated to 1700 C. at a rate of 4° C. per minute. When at 1700° C. was reached, an air bleed was begun into the reactor at a rate of 60 sccm while maintaining a vacuum of 0.5 Ton. The air used was unfiltered and at a relative humidity of 45%. A cold finger penetrating into the reactor is used to actively scavenge the silicon byproducts via condensation and solidification. Reaction conditions were maintained for 6 hrs, with T=1700° C. marking time=0. This process is used without modification for all other examples, with the only modification used for SCNR clusters or whiskers (bulk material) being processed for 24 hrs to ensure complete conversion to fullerene structures. The reactor was then allowed to cool naturally to room temperature. Finished disks were then removed and used as produced.

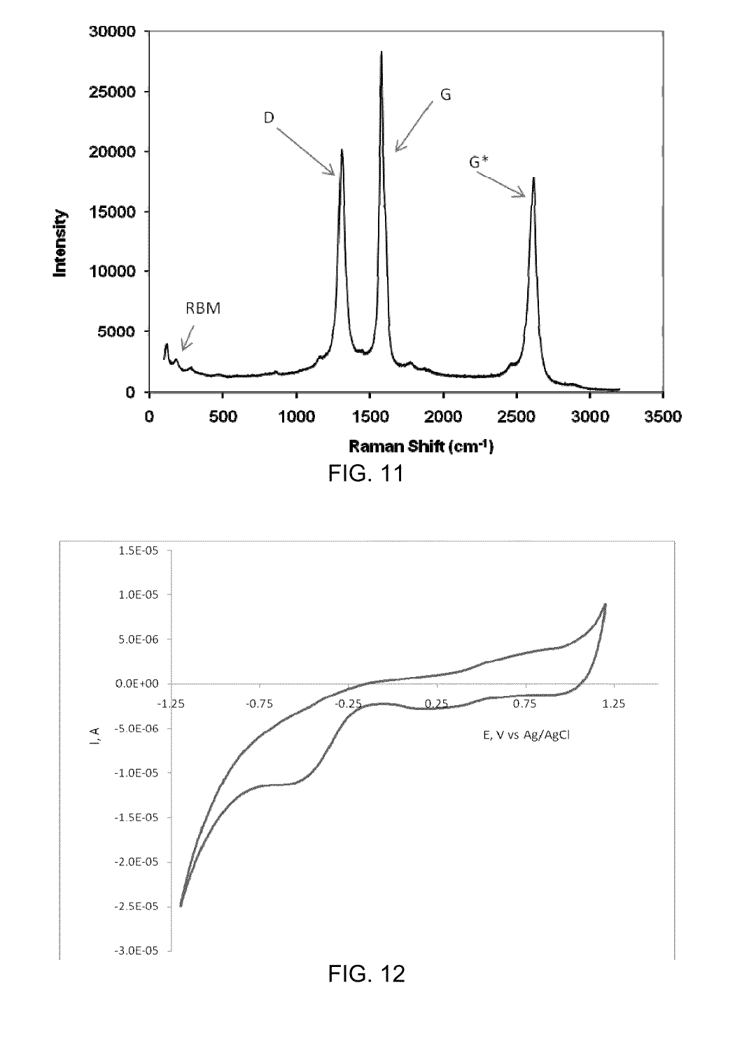

The resulting reactively modified silicon carbide disk includes a surface of fullerene structures having high edge plane character (HEPC). The HEPC provides the reactively modified surface of the disk with unique characteristics, which Applicants have correlated to the Raman Spectrum produced by the reactively modified surface. The reactively modified surface was examined by Raman Spectroscopy using 514 nm and 785 nm excitation laser in air using a Renishaw in Via Confocal Raman Microscope with a 30 second excitation time and 30 second integration time, with two accumulations. FIG. 11 shows that the Raman shift of the HEPC fullerene structures on the reactively modified surface excited with a 785 nm exhibits a D band, a G band, and a G* band. The values of the D, G, and G* bands are shown below in Table 1 (514 nm Excitation Laser) and Table 2 (785 nm Excitation Laser) with additional data of various commercially available carbon nanotube materials.

TABLE 1
Table 1. D, G, and G* Intensity of Fullerene
Materials using a 514 nm Excitation Laser

| | | D Band: | | G Band: |
|---|---|---|---|---|
| | Growth | G Band | | G* Band |
| Material | Process | Ratio | Chirality | Ratio |
| Comparative Examples | | | | |
| Nano Lab Aligned CNT | CVD | 0.46 | Metallic | 10.2 |
| Array | | | | |
| CNI Isolated SWCNT | CVD | 0.04 | Metallic | 100.2 |
| Alfa Asear MWCNTs | CVD | 0.89 | N/A | 1.22 |
| Nano Lab MWCNTs | CVD | 0.81 | N/A | 1.46 |
| Reactively Modified SiC | | | | |
| SCNR Planar 2- | CTCC | 0.08 | Metallic | 0.48 |
| dimensional Array | | | | |
| SCNR Cluster | CTCC | 0.18 | Metallic | 0.74 |
| SCNR Whisker | CTCC | 0.13 | Metallic | 0.66 |
| SCNR Foam 3-dimensional | CTCC | 0.19 | Metallic | 0.58 |
| array | | | | |

Table 1 illustrates the difference between nanostructures produced without a metal growth catalyst and conventionally produced CNTs using a metal catalyst. CVD and are discharge methods generally result in higher D:G ratios than, for example, CTCC produced materials due to amorphous carbon content and nano crystalline carbon from lack of catalyst efficiency. Isolated and purified SWCNTs often display spectra with low D:G ratios and high G:G* ratios due to a largely homogeneous sample of high aspect ratio. A 514 nm laser is more sensitive to “defects” resulting from a non CNT carbon, specifically amorphous carbon from production, than 785 nm. Thus, lower D:G ratios are expected even for high edge plane material using 514 nm vs. 785 nm excitation lasers. This is a result of the contamination of the CNT side walls with amorphous carbon content. Further illustrating the shortcomings of the seed catalyst production processes, is the broadening of the G band itself. This suggests a large distribution of diameters and chiralities. More important than diameter alone, chirality determines the utility of the CNTs (or its derivatives, SCNRs) as electrode materials due to their intrinsic internal resistance. When used in conjunction with a 785 nm laser and other overlapping analytical tools such as TGA and electron microscopy, including HRTEM, the Raman spectra (using a 514 nm excitation laser) provides a great deal of insight into the Edge Plane Character (EPC) of fullerenes. For example, the isolated SWCNT displays a low D:G ratio and high G:G* ratio, indicating its relative EPC is lower than that expected for CTCC grown materials. While CVD grown MWCNTs display higher D:G and G:G* indicating significant carbon contamination when interpreted with overlapping techniques. With prior insight into the structure and contamination (through the utilization of electron microscopy and TGA), Raman can be used to compare fullerenes for EPC.

TABLE 2
Table 2. D, G, and G* Intensity of Fullerene
Materials using a 785 nm Excitation Laser

| | | D Band: | | G Band: |
|---|---|---|---|---|
| | Growth | G Band | | G* Band |
| Material | Process | Ratio | Chirality | Ratio |
| Comparative Examples | | | | |
| Nano Lab Aligned CNT | CVD | 1.78 | Distribution | 10.4 |
| Array | | | | |
| CNI Isolated SWCNT | CVD | 0.83 | Metallic | 45.8 |
| Alfa Asear MWCNTs | CVD | 1.75 | Distribution | 11.96 |
| Nano Lab MWCNTs | CVD | 1.24 | Distribution | 8.11 |
| Reactively Modified SiC | | | | |
| SCNR Planar - 2 | CTCC | 1.18 | Metallic | 1.07 |
| dimensional Array | | | | |
| SCNR Cluster | CTCC | 1.60 | Metallic | 2.38 |
| SCNR Whisker | CTCC | 0.49 | Metallic | 1.36 |
| SCNR Foam 3-dimensional | CTCC | 0.86 | Metallic | 1.82 |
| array | | | | |

Table 2 shows examples of G:D and G:G* ratios using a 785 nm excitation laser from a selection of fullerene materials. When used and interpreted with information gathered from overlapping techniques (TGA/Electron microscopy) and alternative Raman wavelengths (such as 514 nm), insight into the edge plane character can be obtained. Catalyst grown fullerene materials typically display artificially high D:G ratios resulting from non CNT carbons present, including amorphous carbon, and fullerene shells surrounding catalyst particles among other commonly encountered contaminants. Significantly higher G:G* ratios result from low crystalline defects present in the commercially available materials, indicating lower EPC, as compared with CTCC produced materials which display lower G:G* ratios due to higher mechanical strain, or kinks.

Raman can thus be used to help illustrate the homogeneity and edge plane character of the active electrode structure. Inspection of the ratios above yields significant differences between CVD grown and CTCC grown materials. Some of the differences are a result of impurities and non-homogeneity in the fullerene. The remaining component, best illustrated by the G* ratios using a 785 nm laser, better illustrate the HEPC of the materials produced by this process. A distinctly low G:G* ratio using a 785 nm excitation laser characterizes a HEPC material in the absence of contaminating carbon species. Material produced via CTCC exhibit D:G ratios of roughly 1:5 and 1:1 using 514 nm and 785 nm lasers, and G:G* ratios of 1:2 and 2:1 using 514 nm and 785 nm excitation lasers, respectively.

### Example 2

### Nanocarbon Modified Disk Electrode

The reactively modified SiC disk of Example 1 was connected to an electrical lead of 28 gauge copper wire using a conductive silver epoxy to make an electrical connection to the back of the disk. Then the disk and a portion of the lead adjacent to the disk was encapsulated in a PTFE cylinder by pressing the disk into the PTFE cylinder with a 0.004 in press fit, thus forming an electrode.

From the copper wire to the fullerene structures on the reactively modified surface of the disk, the electrode exhibited an electrical resistance of approximately 5 to 7 ohms. No degradation of the layer of fullerene structures was observed electrochemically or visibly throughout the following tests.

### 2.1 Background CV of the Electrode

The electrode was then placed in a solution of 0.1M NaCl buffered to pH 7.2 via 0.05M phosphate buffer to determine the background CV of the electrode. A Pt wire auxiliary electrode and a Ag/AgCl reference electrode, both commercially available from BAS, were used with a Gamry Ref 600 Potentiostat run at a scan rate of 100 mV/s. FIG. 12 is the background CV of the reactively modified disk electrode generated under these conditions.

FIG. 12 shows a typical background scan of the electrode which was essentially unchanged after the first scan and for subsequent scans (not shown). This demonstrates that the electrode has a stable electrochemical background window from approximately −1V to +1V vs Ag/AgCl. Empirically, FIG. 12 shows that the electrode has high purity (no residual reactive metal catalyst content). In contrast, a CVD grown CNT array would be expected to have at least metal catalyst impurities, which would display a transient background current (variable scan to scan) as metal catalyst is dissolved and redeposited. Furthermore, significant amorphous carbon content from process inefficiency would be expected to be present. This form of contamination is particularly excessive in arc and laser ablation synthesis processes.

FIG. 12 also shows that the electrode demonstrates excellent sensitivity to dissolved oxygen, with a reduction wave beginning at roughly −0.2V vs Ag/AgCl. The electrode, therefore, may be useful as/in an oxygen sensor.

### 2.2 Response of the Modified Disk Electrode to a Model Redox Couple

HEPC is indicative of fullerene structures that demonstrate enhanced electron transfer rates. To demonstrate that the HEPC, as evidenced by the Raman Spectrum of FIG. 11, in fact, has superior electron transfer rates, a model redox couple (ferri/ferrocyanide) was used. The electrode was placed in a solution of 4 mM ferri/ferrocyanide in a supporting electrolyte of 0.1M NaCl buffered to pH 7.2 by the addition of 0.05M phosphate buffer. A Pt wire auxiliary electrode and a Ag/AgCl reference electrode, both commercially available from BAS, were used with a Gamry Ref. 600 Potentiostat to perform the experiment with a 5 mV/s scan rate.

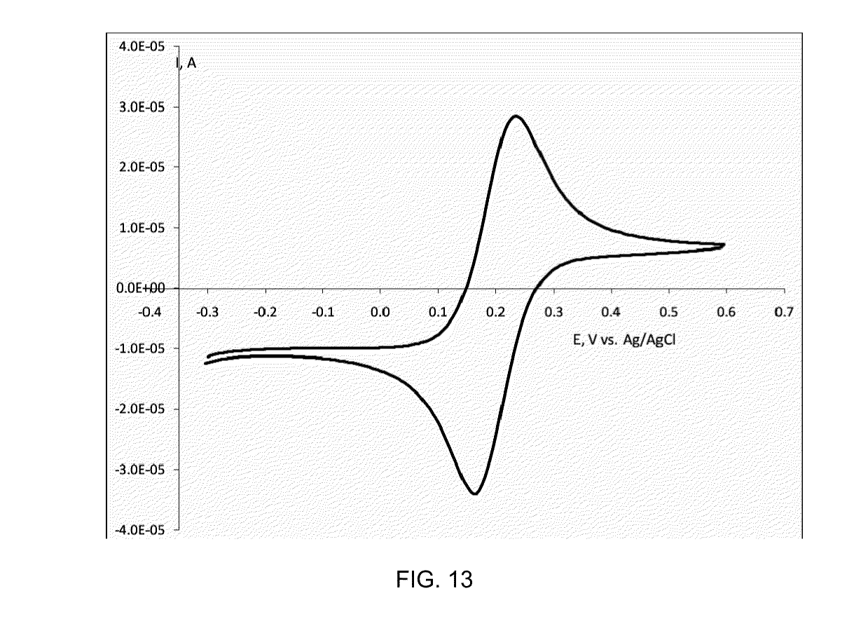

FIG. 13 is a CV of the electrode's response to the ferri/ferrocyanide redox couple. The CV includes a peak separation of 71 mV, with an anodic peak current (iₚₐ) of 28 uA and an cathodic peak current (i_{pc}) of 34 uA. This figure illustrates the fast electron transfer rates associated with edge plane carbon with the mechanically robust nature of glassy carbon, thus providing a unique and valuable set of properties for electrochemical devices.

2.3 Anodic Square Wave Stripping Voltammetry (ASWSV) Detection of Metal Ions in Solution using the Electrode

ASWSV is a commonly used technique to detect and quantify metal species present in various samples such as fresh water, saliva, sea water, and whole blood. Here, the electrode is demonstrated as an in situ environmental sensor for detecting metal species in a water test sample. The same principals would apply if the test matrix were any number of other solutions such as whole blood to plating bath solutions.

Aliquots of standard solutions of Hg⁺², Pb⁺², and Cd⁺² were added to Great Miami River water (obtained from North Dayton, Ohio, conductivity roughly 500 uS—without any filtration or purification) to obtain the test solutions. The electrode was placed in the test solution containing various concentrations of each metal ion or the river water before adding with the metals (to obtain a background scan). The ASWSV technique included a second accumulation time at −1.5V vs Ag/AgCl, during which the metals collected on the fullerene structures of the electrode, followed by a 10 Hz pulse frequency of a 25 mV pulse with a 5 mV step to strip the metals from the electrode. The test solution was stirred for 1 minute prior to the 300 second accumulation time to ensure adequate mixing of the sample. A Pt wire auxiliary electrode and a Ag/AgCl reference electrode, both commercially available from BAS, were used to complete an electrochemical cell. Then, a Gamry Reference 600 Potentiostat/Galvanostat/ZRA was used to perform the analysis.

FIG. 14A is the resulting graph of current versus voltage for a background scan and a scan on a test solution to which each of the metals was added to the river water at a final concentration of 75 ppt. The scan on the test solution containing the metals has three distinct peaks: peak 1 at about −0.72 V; peak 2 at about −0.56 V; and peak 3 at about 0.30 V. Peak 1 corresponds to the presence of Cd⁺². Peak 2 corresponds to the presence of Pb⁺². Peak 3 corresponds to the presence of Hg⁺². The background scan suggests that the river water has very low or negligible levels of the metals before they are added.

FIG. 14B shows the resulting calibration curve when each of the metals was added to the fresh river water at a final concentration of 25, 50 and 75 ppt. That is, three samples were prepared each having the same final concentrations of all three metals (25, 50 and 75 ppt) and then analyzed using the ASWSV technique described above. In FIG. 14B differential or net peak current (baseline and background corrected) is plotted against the concentration of metal ion present. The lines on the graph represent best fit Linear Regression results for each of the three metals. In each case, the correlation coefficient (R²) is greater than 0.99 which confirms that the net peak current measured, for each of the respective peaks, can be used to accurately and simultaneously determine the concentrations of each of the three metals.

### Example 3

### Nanocarbon Modified Foam Electrode

SCNR modified open cell foams were studied for the purpose of characterizing their behavior for bio-fuel cell electrodes and electrochemical double layer capacitors. SiC coated reticulated vitreous carbon foam samples were obtained from ERG Materials and Aerospace Corporation under the name DUOCEL® ceramic foam and diced to roughly 2 mm thick by 5 mm wide by 15 mm long pieces using a diamond saw. The cut pieces were then washed with acetone followed by deionized water to remove and loosen material from the surface. Diced pieces were then placed into the center of a graphite hot zone vacuum reactor and the system evacuated to 1 Torr. Upon reaching 1 Torr, the system was heated to 1700° C. with a ramp rate of 4° C. per minute. Upon reaching 1700° C., an air bleed of 60 sccm was started and continued for 6 hrs while maintaining a pressure of 0.5 Torr. Silicon by-products were actively scavenged from the reaction zone via a cold finger. After 6 hrs, the reactor was then allowed to cool naturally to room temperature. Finished product was then removed. In this way, the SiC was modified to form a layer of fullerene structures, specifically non-aligned SCNRs having HEPC, on its surface.

Finished SCNR modified foam pieces were then assembled into suitable electrodes by the following procedure. Silver conductive epoxy was applied to one end of the foam material and used to connect a 28ga copper wire approximately 9 inches long. Approximately 4 mm of the wire-attached end of the foam piece including the silver epoxy junction and 25 mm of the lead wire were potted within an 8 mm i.d. plastic tube using standard epoxy potting resin.

Literature suggests that kinks in cylindrical fullerenes, such as SCNRs and CNTs, increase the edge plane character of the material while significantly retaining its electrical conductivity. This is not true of other forms of defects, such as interstitial vacancies or inclusions, though they may they contribute to the D band intensity in the Raman spectra for some excitation wavelengths.

### 3.1 Background CV of the Electrode

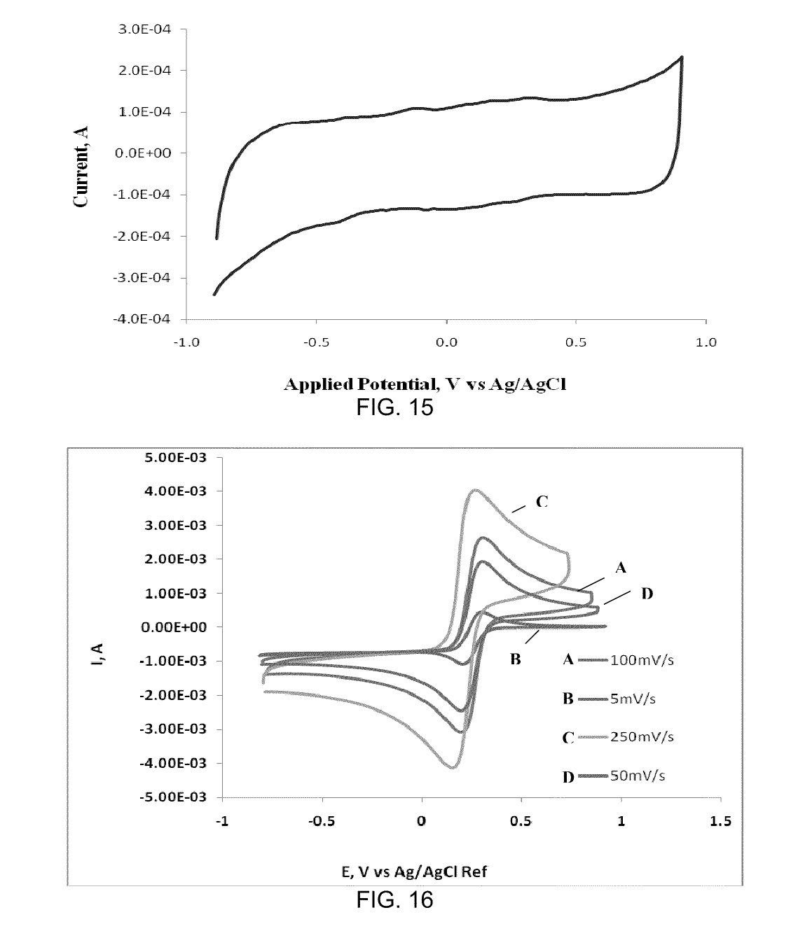

A background scan of the SCNR modified open cell foam electrode (foam electrode) was done to establish the electrochemical window of the foam electrode in an aqueous solution and demonstrate the superior performance of the robustly attached SCNR non-aligned array over conventional CNT electrodes. The electrode was placed in a solution of 0.1M NaCl buffered to pH 7.2 by addition of a 0.05M phosphate buffer to determine the background CV of the electrode. A Pt wire auxiliary electrode and a Ag/AgCl reference electrode, both commercially available from BAS, were placed in the buffered solution. A Gamry Ref 600 Potentiostat with a scan rate of 100 mV/s was used to perform the CV. FIG. 15 shows the background scan of the foam electrode in 0.1M NaCl and 0.05M phosphate buffer solution, degassed via bubbling argon for 15 min to reduce the effect of oxygen reduction as seen in FIG. 12

FIG. 15 demonstrates that the electrode of Example 3 displays a large potential window, similar to EP-HOPG. Also, as expected the foam electrode displayed significant electrochemical capacitance, hinting on utility for fabrication of an electrochemical double layer capacitor, aka an ultracapacitor. The high capacitance is a result of the mesoporous architecture created by the interlaced SCNR coating on the electrode. This architecture creates a greatly extended electrochemically active surface area in comparison with the geometric surface area given by ERG Aerospace. Within this potential window, no unexpected electrochemical waves were observed which would be expected for a catalyst grown nanocarbon material.

### 3.2 Response of the Modified Foam Electrode to a Model Redox Couple

The modified foam electrode was evaluated using 4 mM ferricyanide in 1M KNO₃ using the same procedure and equipment of Example 2.2. FIG. 16 shows a plot of a plurality of CVs of the foam electrode at varying scan rates: A) 100 mV/s; B) 5 mV/s; C) 250 mV/2; and D) 50 mV/s. The traces shown were corrected for high internal resistance of the electrode due to the carbon epoxy used to connect the lead to the foam as well as a significant internal resistance inherent with the SiC layer on the foam electrode. The combined internal resistance of the electrode was approximately 147 ohms. These results indicate that the modified foam electrode exhibits fast electron transfer which is characteristic of HEPC material.

### 3.3 Direct Electron Transfer of a Redox Enzyme to a SCNR Modified Foam Electrode

Another modified foam electrode, made according to the procedures discussed above, in this Example, was further treated to have redox enzyme functionality. Prior to wire attachment and potting the crystalline nanocarbon coated foam was cleaned and surface conditioned by immersion in 70% concentrated nitric acid for 10 hours (overnight) at room temperature, and extensively rinsed with pure water. The conditioned modified foam piece was then built up into an electrode as above. A solution of simplified nitrate reductase SNAR-2, that is 10-40 μL of 3.2 mg/mL pure enzyme in water, was brushed upon the surface of the exposed foam using a very fine pipette tip until the foam surface was wetted by protein adsorption, taking about 15 minutes at room temperature, and incubating an additional 10 minutes. The enzyme solution soaked foam was then incubated a further 5 minutes at 38° C. at saturating humidity. The excess enzyme solution was wicked away from the foam using a laboratory tissue wipe and the adherent droplets were removed using a few blasts of pressurized inert gas. The enzyme modified SCNR coated foam electrode was dried for one hour in ambient air. The electrode was then cured at room temperature for twelve hours or more over fresh granular calcium sulfate desiccant in a low vacuum (less than 200 mm Hg). No further coatings were used on this electrode, and it is referred to as the “enzyme electrode” in the rest of this example.

Enzyme-Catalyzed Electrochemical Reduction of Nitrate to Nitrite

The working buffer for testing the enzyme electrode was 50 millimolar MOPS buffer (3-[N-morpholino]propanesulfonic acid, used as the hemisodium salt) adjusted to pH 7.20 with NaOH if necessary. Stock solutions of 100 PPM NO₃⁻ as N from KNO₃ and 100 PPM NO₂⁻ as N from NaNO₂ were made with the MOPS buffer, as were the working dilutions. The enzyme electrode was placed in 30.0 mL of MOPS buffer in a 50 mL electrode cell and continuously sparged with ultrapure argon gas at 100 ml/min. No chemical reducing agents or electron transfer mediators were present in this cell. A Pt wire auxiliary electrode and a Ag/AgCl reference electrode were placed in the cell, both commercially available from BAS. A 1.0 mL sample of this solution was withdrawn for later testing. A Gamry Ref. 600 Potentiostat with a scan rate of 100 mV/s was used to perform the CV shown in FIG. 17. This plot shows the response of the enzyme electrode after the addition of 0.67 mM potassium nitrate (9.4 PPM NO₃⁻—N) to the solution containing the electrode. This plot clearly shows a small oxidation wave centered at about +0.15 V vs. Ag/AgCl and a small reduction wave centered at about +0.05V vs. Ag/AgCl that are believed to be associated with the DET between the enzyme and the electrode surface.

Analysis of Nitrite Appearance after Electrochemical Reduction

In a second set of experiments the same enzyme electrode was poised at −400 mV versus the Ag/AgCl reference electrode and 1.0 mL samples were withdrawn at successive time intervals for testing for the presence of Nitrite which is the product of the enzyme catalyzed reduction of Nitrate.

The generation of nitrite from nitrate was analyzed by a standard colorimetric assay known as the Griess reaction. An SAN diazotization solution was comprised of 10.0 g of sulfanilamide dissolved in sufficient 3.0 Normal hydrochloric acid to make one liter of solution. A NED coupling solution was comprised of 0.20 g of naphthylene-ethylenediamine dihydrochloride in sufficient pure water to make one liter of solution. To perform the color reaction a 500 μL sample aliquot is mixed with 500 μL of the SAN solution and incubated at room temperature for up to 1 minute. Then 500 μL of the NED solution is added with mixing and incubated at least five minutes. The amount of magenta-colored diazo dye generated is linearly proportional to the amount of nitrite present in the sample. This amount is quantitated by reading the solution absorbance on a laboratory spectrophotometer at 540 nm wavelength. A standard curve is generated by treating a set of nitrite standard solutions of known concentration by the same analysis procedure and obtaining absorbance measurements for these. The known and unknown values for nitrite are related by proportional comparison. The absence of inherent nitrite in the buffer or the nitrate stock solution is checked by analysis of samples of each by the same procedure. The absence of inherent nitrite in the enzyme solution used for coating is checked by analysis of samples of it by the same procedure. The absence of pre-activated reduced enzyme in the enzyme solution used for coating is checked by incubating samples of the enzyme solution with nitrate then analyzing these by the same procedure.

The same procedure was also performed on a second SCNR coated foam electrode identical in all respects except it was lacking any enzyme, and is described as a “bare electrode”.

The results of these tests are shown in Table 3 below.

TABLE 3
NITRITE ANALYSIS RESULTS

| Sample ID | Absorbance | PPB of Nitrite as N |
|---|---|---|
| min = time poised at −400 mV | @ 540 nm | (calc from curve) |
| deionized water 1 | −0.003 | −14.6 |
| deionized water 2* | 0.016 | 0 |
| bulk buffer stock* | 0.018 | 0 |
| 5 PPB nitrite std* | 0.022 | 5 |
| 10 PPB nitrite std* | 0.025 | 10 |
| 20 PPB nitrite std* | 0.040 | 20 |
| 50 PPB nitrite std* | 0.077 | 50 |
| 100 PPB nitrite std* | 0.141 | 100 |
| cell buffer | 0.020 | 3.7 |
| 100,000 PPB nitrate stock | 0.013 | −1.7 |
| Bare Electrode | | |
| bare electrode + NO₃, 0 min | 0.016 | 0.7 |
| bare electrode + NO₃, 3 min | 0.017 | 1.5 |
| bare electrode + NO₃, 5 min | 0.017 | 1.1 |
| bare electrode + NO₃, 10 min | 0.015 | −0.1 |
| bare electrode + NO₃, 15 min | 0.019 | 2.9 |
| Enzyme Electrode | | |
| enzyme electrode + NO₃, 0 min | 0.020 | 3.4 |
| enzyme electrode + NO₃, 3 min | 0.067 | 41.1 |
| enzyme electrode + NO₃, 5 min | 0.071 | 44.3 |
| enzyme electrode + NO₃, 10 min | 0.067 | 41.5 |
| enzyme electrode + NO₃, 15 min | 0.069 | 42.6 |
| enzyme electrode + NO₃, 20 min | 0.067 | 41.6 |
| enzyme prep solution | no color | 0 |
| enzyme prep solution + NO₃ | no color | 0 |

*used to calculate the standard curve by unweighted linear regression. Deionized water was used in the reference cell. 10 mm pathlength matched semi-micro quartz cells were used in a Shimadzu UV-2401 PC dual beam spectrophotometer.

The results shown in Table 3 demonstrate that Nitrite is produced in statistically significant amounts only when the enzyme is present and in intimate contact with the electrode. (Negative concentrations of Nitrite indicated in the Table are artifacts associated with resolving the very low Absorbances measured on these specific samples.) This is evidence that DET is occurring between the Nitrate Reductase enzyme and the SCNR coated foam electrode surface.

### Example 4

### Bulk Nanocarbon Electrode

### 4.1 Nanocarbon Paste Electrode

Silicon carbide nanopowder (<100 nm) was obtained from Sigma Aldrich (product number 594911) and used without further treatment or processing. SiC nanopowder was loaded into the vacuum reactor on 12 in by 12 in smooth graphite trays. The reactor was then evacuated to 1 Torr, followed by heating to 1700° C. with a ramp rate of 4° C. per minute. An air bleed into the reactor was then started at 60 sccm, while maintaining a reactor pressure of 0.5 Torr. Silicon byproducts were actively removed from the reaction zone via collection by a cold finger. The reaction was allowed to proceed for 24 hours to ensure largely complete conversion. At 24 hrs, the reactor was shut down and allowed to cool naturally to room temperature, then the material was collected and used.

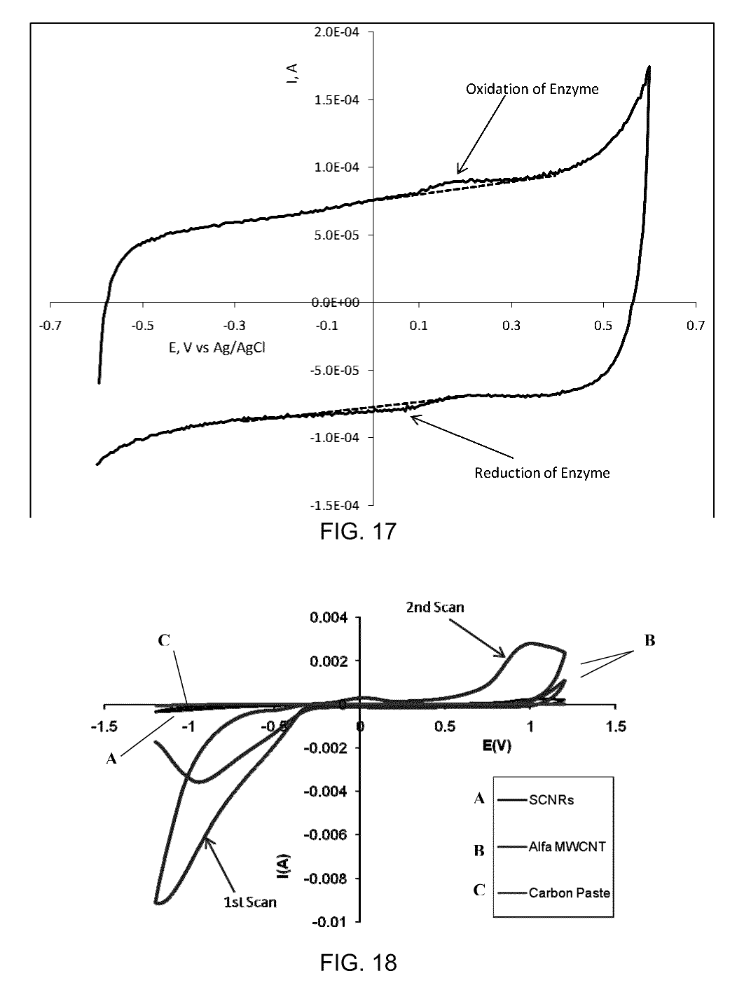

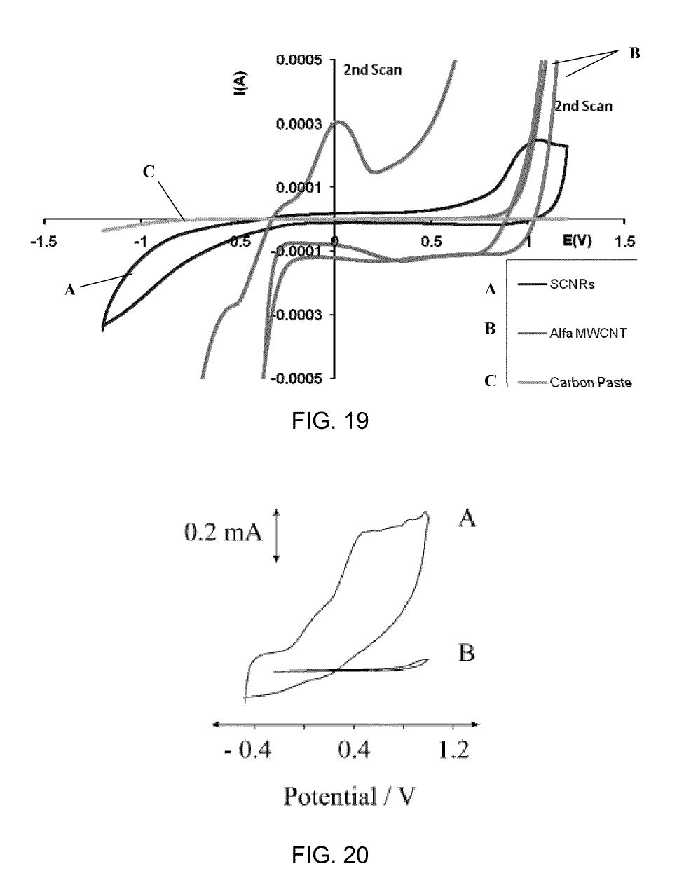

Similar to Example 2, it is useful to know the electrochemical background window as determined via cyclic voltammetry for the bulk nanocarbon electrode, as well as compare it to conventional carbon materials including CVD grown CNTs. This can be seen in FIGS. 18-19, which show typical background scans of electrodes fabricated with commercially available carbon paste, MWCNT paste, and SCNR paste electrodes. The nanocarbon paste electrodes were made by: 1) milling commercially available CVD produced MWCNTs from NanoLab and milling the bulk crystalline nanocarbon made herein (SCNR clusters) that has HEPC; 2) placing each milled nanocarbon into mineral oil at 50 wt %; and 3) placing each oil-nanocarbon mixture into a carbon paste electrode holder, specifically a Stationary Voltammetry Electrode MF-2010/CF-1010 commercially available from BAS Inc., to contain and make electrical contact with the respective pastes. The electrodes were then immersed in a 1.0M KNO₃ aqueous solution with a Pt wire auxillary electrode and a Ag/AgCl reference electrode, both available from BAS, and cyclic voltammetry was performed using a scan rate of 100 mV/sec.

FIG. 18 shows both the first and second scans performed on the paste electrodes and allows a comparison of the background currents obtained. The background current of CVD grown MWCNTs (B in FIGS. 18-19) is much greater on the first scan than the second and continues to decay for several scans thereafter. FIG. 19 shows the data presented in FIG. 18 using an altered scale to allow comparision of the three electrode materials without scale compression due to the oxidation-reduction processes dominating the CVD grown CNT voltammograms at potential extremes. The oxidation currents for the paste electrode begins to increase at roughly 0.75V, as expected, for all of the carbon electrode materials. This is likely due to progressive oxidation of the electrode via electrochemical reaction in the presence of nitrate in solution. Regardless of the number of scans the background currents of MWCNTs remain elevated compared to the electrode containing Applicants' modified carbon nanostructures (labeled as A on FIGS. 18-19 (the SCNRs)) which has background currents more comparable to the low background currents seen on commercially available carbon paste electrodes. At 0.5V vs. the reference during the oxidation scan, the MWCNT (B in FIGS. 18-19) has a background current of 290 μA, the SCNRs (A in FIGS. 18-19) of 1.25 μA, and the BAS (C in FIGS. 18-19) of 22 nA.

### 4.2 SCNR Modified Highly Ordered Pyrolytic Graphite (“HOPG”)

Carbon nanotubes are often attributed with electrocatalytic properties, most frequently with hydrogen peroxide. In order to demonstrate that significant residual catalyst (typically metal impurities) is present in commercial CNT samples, HOPG immobilized electrodes were fabricated. Electrodes were prepared by immobilizing the bulk carbon nanostructures under investigation onto a basal plane graphite electrode. The basal plane graphite substrate by itself generally displays slow heterogeneous electron transfer rates when species present in the solution are probed, thus providing an ideal immobilization platform for nanomaterials. The fullerenes studied were dispersed into methanol at 0.01 g/mL concentration via ultrasonication. A volume of the resulting solution was then added to the basal plane HOPG electrode to achieve the desired nanocarbon loading, and the carrier solvent was allowed to evaporate under ambient conditions. This general procedure was used in the following examples.

Hydrazine is electrochemically active at metal surfaces, but not on carbon due to large overpotential. Thus, hydrazine provides a convenient electrochemical probe to determine the presence of detrimental residual metal contamination in the carbon nanotubes. This electrochemical probe (hydrazine) is highly sensitive to metallic impurities, since it can only be oxidized at a metal containing electrode and not on a pure carbon electrode. To test the carbon nanostructures in the above describe electrode, the electrode was placed into a solution of 1 mM hydrazine containing a phosphate buffer to adjust the pH to 7.1. Thereafter, a CV scan of 1 mV/s was performed. The CV scan of the commercially available MWCNTs is scan A in FIG. 20. FIG. 20 also includes a CV scan of an electrode containing the inventive bulk crystalline carbon nanostructures (SCNR clusters) B.

FIG. 20 illustrates that the presence of the metal impurities in commercially available MWCNTs can grossly affect electrochemical behavior when such materials are incorporated into electrodes. The presence of a large electrochemical oxidation wave at about +460 mV (vs. SCE), confirms the presence of metal impurities in the electrode fabricated using commercially available MWCNTs (NanoLab) and the absence of such an electrochemical oxidation wave in the scan on the electrode containing SCNR clusters confirms the absence of metal impurities in the SCNRs.

### 4.3 Response of SCNR Modified Basal Plane HOPG to a Model Redox Couple

Similar to Example 2.2, it is desirable to investigate the performance of an enzyme containing modified carbon nanostructure with a model redox couple, such as ferri/ferrocyanide. The loading of the SCNR clusters was increased in 20 μg increments from 20 μg to 80 μg immobilized on the basal plane pyrolytic graphite surface to form four electrodes with different amounts of SCNR clusters, but using the same basal plane pyrolytic graphite as an electrode substrate.

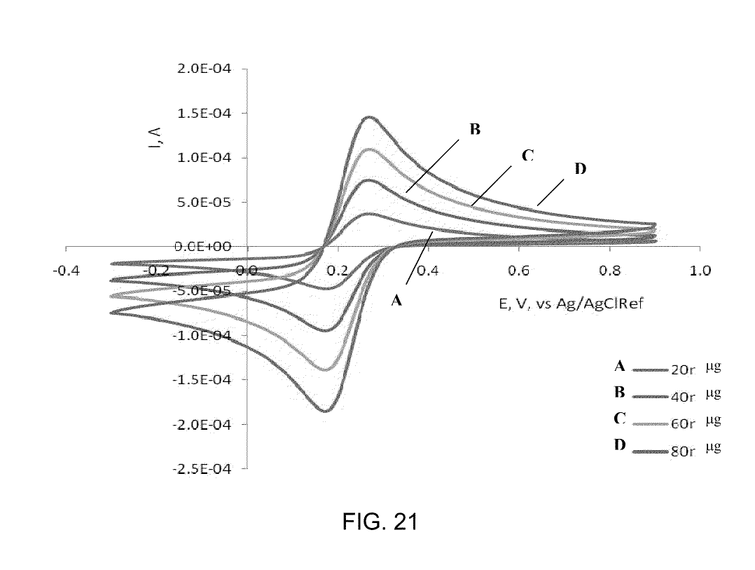

Each of the electrodes were placed separately into a 4 mM potassium ferricyanide/1M KNO₃ solution and scanned at a 10 mV/s scan rate using the electrodes and equipment discussed above in Examples 2 and 3. FIG. 21 shows the effect of increasing SCNR cluster loadings on the cyclic voltammograms of ferricyanide at the modified HOPG. In particular, FIG. 21 shows that the electrochemical response of the electrode is dominated by the SCNRs and not the basal plane HOPG.

### 4.4 Bulk Nanocarbon Electrode TGA

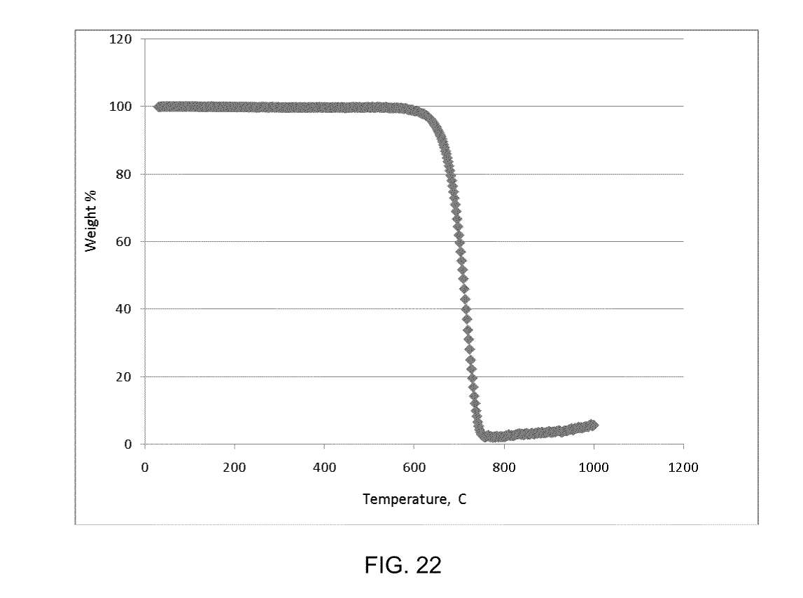

Thermal gravimetric analysis (TGA) is used to indirectly gauge the relative purity or homogeneity of a carbon nanomaterial. Typically TGA is carried out in air. A sample is placed into the analysis chamber, and temperature ramped at a defined rate, typically 10° C./minute, to a final temperature high enough to ensure all carbon material will be completely oxidized to CO₂. It is well known in the literature that non crystalline carbon, for example carbon black or acetylene black, will oxidize well before crystalline carbon due to the enhanced chemical stability afforded the material through crystallization. Thus it becomes possible to gauge, with overlapping techniques, the degree of crystallinity of the carbon present. Additional insight may be gained into the homogeneity of the crystalline carbon present. Significantly different structures, for example “Dixie cup” vs. “straight” vs. “bamboo” will each oxidize at slightly different temperatures. FIG. 22 shows the TGA of a SCNR Whisker (a free standing entangled mass of CNTs or SCNRs) material in air. This figure illustrates the highly homogeneous nature of the crystalline carbon present as no significant loss of mass is seen below 500° C. The extremely low mass change observed below 500° C. is likely due to moisture desorption from the material during temperature ramping.

It will be appreciated that while the invention has been described in detail and with reference to specific embodiments, numerous modifications and variations are possible without departing from the spirit and scope of the invention as defined by the following claims.

What is claimed is:

1. An electrode comprising:
a fullerene covalently bonded to a conductive carbide, the fullerene being an aligned or non-aligned array; wherein the electrode is characterized in that the peak separation of a cyclic voltammogram for the conductive carbide having a surface layer of the fullerene is less than about 150 mV at a scan rate of 5 mV/s in a 4 mM ferricyanide, 1M KCl solution.

2. The electrode of claim 1 wherein the peak separation is less than about 100 mV.

3. The electrode of claim 1 wherein the peak separation is less than about 75 mV.

4. The electrode of claim 1 wherein the peak separation is less than about 65 mV.

5. The electrode of claim 1 wherein the peak separation is about 150 to 59.1 mV.

6. The electrode of claim 1 further comprising about 50% or less non-crystalline carbon and about 5% or less of a transition metal that interferes with the ability of the active electrode structure to transfer electrons or detect an analyte.

7. The electrode of claim 2 wherein the transition metal is about 1% or less of the active electrode structure.

8. The electrode of claim 2 wherein the non-crystalline carbon is about 5% or less of the active electrode structure.

9. The electrode of claim 2 wherein the non-crystalline carbon is about 1% or less of the active electrode structure.

10. The electrode of claim 1 wherein the conductive carbide, prior to having the fullerene covalently bonded thereto, has an ohmic resistance of less than about 5000 Ω/sq.

11. The electrode of claim 10 wherein the conductive carbide has an ohmic resistance of less than about 1000 Ω/sq.

12. The electrode of claim 11 wherein the conductive carbide has an ohmic resistance of less than about 100 Ω/sq.

13. The electrode of claim 12 wherein the conductive carbide has an ohmic resistance of less than about 10 Ω/sq.

14. The electrode of claim 13 wherein the conductive carbide has an ohmic resistance of less than about 10 Ω/sq.

15. The electrode of claim 14 wherein the conductive carbide has an ohmic resistance of less than about 0.1 Ω/sq.

16. The electrode of claim 1 further comprising an electrical lead electrically conductively coupled to the conductive carbide.

17. The electrode of claim 16 wherein the active electrode structure further comprises at least one of a binder, a filler, and combinations thereof.

18. The electrode of claim 1 wherein the fullerene is a non-aligned, entangled array.

19. The electrode of claim 18 wherein the fullerene is formed by a carbo-thermal carbide conversion that is essentially free of metal catalyst.

20. The electrode of claim 19 wherein the metal catalyst is present in an amount less than about 500 ppm.

21. The electrode of claim 20 wherein the metal catalyst is present in an amount less than about 100 ppm.

22. The electrode of claim 1 wherein the carbide includes silicon carbide.

23. The electrode of claim 22 wherein the silicon carbide is an n-doped silicon carbide.

24. The electrode of claim 1 wherein the fullerenes are selected from the group consisting of carbon nanotubes, carbon nanorods, or combinations thereof.

25. The electrode of claim 24 wherein the fullerenes display high edge plane character.

26. The electrode of claim 25 including 0.1% or less of a non-crystalline carbon and 0.1% or less of a metal catalyst.

27. The electrode of claim 26 characterized by a G band Raman signature to G* band Raman signature of about 10:1 to about 1:5 at 514 nm excitation and of about 12:1 to about 1:5 at 758 nm excitation.

28. The electrode of claim 1 wherein the carbide has at least a 30% crystalline carbide content.

29. The electrode of claim 1 wherein the carbide has at least a 70% crystalline carbide content.

30. The electrode of claim 1 wherein the carbide has at least a 99% crystalline carbide content.

31. The electrode of claim 1 wherein the fullerenes include a 2-dimensional array of fullerenes.

32. The electrode of claim 1 wherein the conductive carbide is substantially converted to fullerenes such that the fullerenes are a free standing mass of fullerenes.

33. The electrode of claim 1 wherein the fullerene is modified to include a transition metal that enhances the ability of the active electrode structure to transfer electrons or detect an analyte, provided that the transition metal does not function as a metal catalyst for fullerene growth.

34. The electrode of claim 33 wherein the transition metal is a noble metal.

35. An active electrode structure comprising:
a fullerene covalently bonded to a conductive carbide, wherein the conductive carbide, prior to having the fullerene covalently bonded thereto, has an ohmic resistance of less than about 5000 Ω/sq.

36. The active electrode structure of claim 35 wherein the conductive carbide has an ohmic resistance of less than about 100 Ω/sq.

37. The active electrode structure of claim 35 wherein the conductive carbide has an ohmic resistance of less than about 10 Ω/sq.

38. The active electrode structure of claim 35 wherein the conductive carbide has an ohmic resistance of less than about 1 Ω/sq.

39. The active electrode structure of claim 35 wherein the fullerenes comprise about 50% or less non-crystalline carbon and about 5% or less of a transition metal that interferes with the ability of the active electrode structure to transfer electrons or detect an analyte.

40. The active electrode structure of claim 39 wherein the transition metal is about 1% or less of the active electrode structure.

41. The active electrode structure of claim 39 wherein the non-crystalline carbon is about 5% or less of the active electrode structure.

42. The active electrode structure of claim 39 wherein the non-crystalline carbon is about 1% or less of the active electrode structure.

43. The active electrode structure of claim 35 wherein the fullerene is a non-aligned, entangled array.

44. The active electrode structure of claim 35 wherein the fullerene is formed from the carbide substantially without a metal catalyst.

45. The active electrode structure of claim 44 wherein the metal catalyst is present in an amount less than 500 ppm.

46. The active electrode structure of claim 45 wherein the metal catalyst is less than about 1 ppm of the active electrode structure.

47. The active electrode structure of claim 35 wherein the carbide includes silicon carbide.

48. The active electrode structure of claim 35 wherein the conductive carbide is substantially converted to fullerenes such that the fullerenes are a free standing mass of fullerenes.

49. A sensor comprising:
a fullerene covalently bonded to a conductive carbide, the fullerene being an aligned or non-aligned array;
wherein the carbide having a surface coating of the fullerene is characterized in that the peak separation of a cyclic voltammogram for the conductive carbide having a surface layer of the fullerene is less than about 150 mV at a scan rate of 5 mV/s in a 4 mM ferricyanide, 1M KCl solution;
wherein the active electrode structure further comprises a protein coupled to the fullerene.

50. A sensor of claim 49 wherein the protein provides the active electrode structure with the capability of detecting nitrate

51. The sensor of claim 50 wherein the protein includes a heme group.

52. The sensor of claim 51 wherein the protein includes nitrate reductase.

53. The sensor of claim 52 wherein the nitrate reductase is a simplified eukaryotic nitrate reductase.

54. The sensor of claim 49 wherein the peak separation is less than about 75 mV.

55. The sensor of claim 49 wherein the peak separation is about 59.1 mV.

56. The sensor of claim 49 wherein the conductive carbide, prior to having the fullerene covalently bonded thereto, has an ohmic resistance of less than about 100 Ω/sq.

57. The sensor of claim 49 wherein the conductive carbide, prior to having the fullerene covalently bonded thereto, has an ohmic resistance of less than about 10 Ω/sq.

58. The sensor of claim 49 wherein the conductive carbide, prior to having the fullerene covalently bonded thereto, has an ohmic resistance of less than about 1 Ω/sq.

59. A process for detecting or quantifying an analyte in a test solution, the process comprising;
placing an electrode in a test solution containing an analyte, the electrode including fullerenes produced by conversion from a carbide;
depositing the analyte on the electrode by operating the electrode at a potential that deposits the analyte on the electrode;
electrochemically stripping the analyte from the electrode by voltammetric scanning of the electrode through a range of potentials that progressively removes the analyte; and
determining the identity of the analyte based upon the voltage at which the analyte is stripped from the electrode.

60. The process of claim 59 wherein determining the identity of the analyte includes correlating a measurement corresponding to a change in oxidation state of the analyte to its identity.

61. The process of claim 59 wherein quantifying that amount of the analyte present includes determining the peak height (current) or integrated peak current (charge) from a graph of the differential current versus the electric potential.
